(19) United States
(12) Patent Application Publication
(10) Pub. No.: US 2025/0264921 A1
(43) Pub. Date: Aug. 21, 2025

(54) Integrated liquid and air cooling unit for cooling a datacenter

(71) Applicant: STREAM U.S. DATA CENTERS, L.L.C., a Texas limited liability company, d/b/a Stream Data Centers, Dallas, TX (US)

(72) Inventors: Stuart Douglas Lawrence, Austin, TX (US); Michael Licitra, Halesite, NY (US)

(21) Appl. No.: 19/057,677

(22) Filed: Feb. 19, 2025

Related U.S. Application Data
(60) Provisional application No. 63/555,813, filed on Feb. 20, 2024.

(51) Int. Cl. G06F 1/20; H05K 7/20

(52) U.S. Cl. CPC G06F 1/206; H05K 7/20145; H05K 7/20172; H05K 7/20272; H05K 7/20736; H05K 7/20781; H05K 7/20836

(57) ABSTRACT

An integrated liquid and air cooling unit is described that has a framework constructed to contain and support a weight of one or more air-based cooling modules and one or more direct liquid cooling modules, in a same real estate space, to supply air-based cooling and direct liquid cooling to Information Technology (IT) computing equipment housed in a datacenter.

### RELATED APPLICATION

This application claims priority to and the benefit of under 35 USC 119 of U.S. provisional patent application titled “An integrated liquid and air cooling unit for a data center,” filed Feb. 20, 2024, Ser. No. 63/555,813, which is incorporated herein by reference in its entirety.

### NOTICE OF COPYRIGHT

A portion of this disclosure contains material that is subject to copyright protection. The copyright owner has no objection to the facsimile reproduction by anyone of the material subject to copyright protection as it appears in the United States Patent & Trademark Office's patent file or records, but otherwise reserves all copyright rights whatsoever.

### FIELD

Embodiments of the design provided herein generally relate to Heat rejection from equipment in a facility. In an embodiment, the design relates heat rejection from IT equipment in a data center through air and/or liquid modalities that can provide one or more air-based cooling modules, one or more direct liquid cooling modules, and any combination of these.

### BACKGROUND

Information Technology (“IT”) operations are a crucial aspect of most organizational operations in the western world. One of the main concerns is business continuity. Companies rely on their information systems to run their operations. If a system becomes unavailable, company operations may be impaired or stopped completely. It is necessary to provide a reliable infrastructure for IT operations, in order to minimize any chance of disruption.

### SUMMARY

In an embodiment, an integrated liquid and air cooling unit is described that has a framework constructed to contain and support a weight of one or more air-based cooling modules and one or more direct liquid cooling modules, in a same real estate space, to supply air-based cooling and direct liquid cooling to Information Technology (IT) computing equipment housed in a datacenter.

### DRAWINGS

The drawings and other documents submitted with this document refer to some embodiments of the design provided herein in. Again, additional drawings and reference documents to this concept are submitted with this document. One skilled in the art, such as the inventors, are readily familiar with how these documents relate to each other.

FIG. 1 illustrates a perspective view of a block diagram of an embodiment of an example integrated liquid and air cooling unit that has a framework structured to contain and support a weight of one or more air-based cooling modules and one or more direct liquid cooling modules, in the same real estate space/footprint, to supply the air-based cooling and the direct liquid cooling to the Information Technology (IT) computing equipment housed in a datacenter.

FIG. 2A illustrates a perspective view of a block diagram of an embodiment of an example integrated liquid and air cooling unit that has a single direct liquid cooling module stacked on top of a single air-based cooling module.

FIG. 2B illustrates a perspective view of a block diagram of an embodiment of an example integrated liquid and air cooling unit that has a single direct liquid cooling module stacked on top of two air-based cooling modules.

FIG. 3 illustrates a frontal view of a block diagram of an embodiment of an example air-based cooling module with a set of three fans and an associated air coil.

FIG. 4 illustrates a perspective view of a block diagram of an embodiment of an example integrated liquid and air-cooling unit that has three air-based cooling modules stacked on top of each other.

FIG. 5 illustrates a perspective view of a block diagram of an embodiment of an example direct liquid cooling module that has its own casing and internal components including a heat exchanger, a T-strainer, a pump, a pressure independent control valve, and its own controller.

FIG. 6 illustrates a frontal view of a block diagram of an embodiment of an example direct liquid cooling module with the heat exchanger, the T-strainer, the pump, and the pressure independent control valve that is fitted with a fast acting modulating actuator and can be configured to not be able to close completely.

FIG. 7 illustrates a frontal view of a block diagram of an embodiment of an example integrated liquid and air-cooling unit that has two direct liquid cooling modules stacked on top of a single air-based cooling module.

FIG. 8A illustrates a perspective view of a block diagram of an embodiment of a backside an example integrated liquid and air-cooling unit that has two air-based cooling modules stacked on top of a single direct liquid cooling module.

FIG. 8B illustrates a perspective view of a block diagram of an embodiment of a frontside an example integrated liquid and air-cooling unit that has two air-based cooling modules, each with their wall of filters, stacked on top of a single direct liquid cooling module.

FIG. 9 illustrates a side perspective view of a block diagram of an embodiment of an example integrated liquid and air-cooling unit that has a direct liquid cooling module stacked on top of an air-based cooling module with a common piping manifold installed on a side of the integrated liquid and air cooling unit to supply a cooling fluid from the facility cooling water supply.

FIG. 10 illustrates a perspective view of a block diagram of an embodiment of a backside of an example integrated liquid and air-cooling unit that has a direct liquid cooling module stacked on top of an air-based cooling module with a common piping manifold connecting to a side of the integrated liquid and air cooling unit to supply a cooling fluid from the facility cooling water supply.

FIG. 11A illustrates a perspective view of a block diagram of an embodiment of a front side an example integrated liquid and air cooling unit that has a frame and structure of the integrated liquid and air cooling unit constructed with a common piping manifold integrated onto the integrated liquid and air cooling unit such that a first ratio of air-based cooling modules compared to direct liquid cooling modules is installed on the integrated liquid and air cooling unit at day one of an operation of the datacenter, and then be configurable to be a second ratio of air-based cooling modules compared to direct liquid cooling modules installed on the integrated liquid and air cooling unit at a later day of an operation than day one of the datacenter in order to supply a different heat removal need of the IT computing equipment in a future operation of the datacenter.

FIG. 11B illustrates a perspective view of a block diagram of an embodiment of a front side an example integrated liquid and air cooling unit that has a frame and structure of the integrated liquid and air cooling unit constructed with a common extended piping manifold (Extension kit noted) integrated onto the integrated liquid and air cooling unit such that a second ratio of air-based cooling modules compared to direct liquid cooling modules is installed on the integrated liquid and air cooling unit at a future day of an operation of the datacenter.

FIG. 12A illustrates a top-down plan view of a diagram of an embodiment of an example a direct liquid cooling module that has its own casing and internal components including a heat exchanger, a T-strainer, a Basket Strainer or equivalent cartridge or Bag Filter, a modulating pressure independent control valve, a pump, and necessary pressure and flow sensors.

FIG. 12B illustrates a top-down view of a diagram of an embodiment of an example an air-based cooling module that has its own casing, a set of two or more fans, an air coil, a set of air filters.

FIG. 13A illustrates a top-down view of a diagram of an embodiment of an example a direct liquid cooling module with similar components arranged slightly differently than FIG. 12A.

FIG. 13B illustrates a top-down view of a diagram of an embodiment of an example an air-based cooling module.

FIG. 14 illustrates an example cross sectional elevation building layout block diagram of data halls utilizing an embodiment of an example integrated liquid and air cooling unit.

FIG. 15A illustrates an example isometric view of data halls (on two building levels) utilizing an embodiment of an example integrated liquid and air cooling unit.

FIG. 15B illustrates an example cross isometric view of a data hall Technical Water System (also commonly referred to as Technology Cooling System or TCS) utilizing an embodiment of an example integrated liquid and air cooling unit.

FIG. 16 illustrates a block diagram of an embodiment of an example computing device that can be a part of the integrated liquid and air cooling unit and data center equipment discussed herein.

FIG. 17 illustrates a block diagram of an embodiment of the modules with a supply water temperature sensed by a sensor on the technology cooling fluid leaving side and facility cooling fluid temperature sensed by sensors on the facility cooling fluid entering and leavings sides, and the flow rates and the Delta Ts are aligned for the amount of heat that is being rejected.

These and other features of the design provided herein can be better understood with reference to the drawings, description, and claims, all of which form the disclosure of this patent application. While the design is subject to various modifications, equivalents, and alternative forms, specific embodiments thereof have been shown by way of example in the drawings and will now be described in detail. It should be understood that the design is not limited to the particular embodiments disclosed, but—on the contrary—the intention is to cover all modifications, equivalents, and alternative forms using the specific embodiments.

### DESCRIPTION

In the following description, numerous specific details are set forth, such as examples of specific data signals, named components, number of servers in a system, etc., in order to provide a thorough understanding of the present design. It will be apparent, however, to one of ordinary skill in the art that the present design can be practiced without these specific details. In other instances, well known components or methods have not been described in detail but rather in a block diagram in order to avoid unnecessarily obscuring the invention. Thus, the specific details set forth are merely examples. The specific details may be varied from and still be within the spirit and scope of the invention. The following drawings and text describe various example implementations of the design.

The integrated liquid and air cooling unit replaces the need for two separate pieces of cooling equipment: a traditional CRAH (computer room air handler) or fan coil wall and a Liquid to Liquid Cooling Distribution unit, with this integrated solution. The integrated air and direct liquid cooling unit can be an IT equipment (e.g., server) cooling unit. The integrated liquid and air cooling unit provides a modular data center cooling system that can be provisioned for varying combinations of direct liquid cooled IT equipment and air-cooled IT equipment in the same space at the same time, without impacting space allocation and recertification issues for mechanical and electrical systems supporting the cooling system for a facility housing a large amount of heat generating equipment, such as IT computing system housed in a data center.

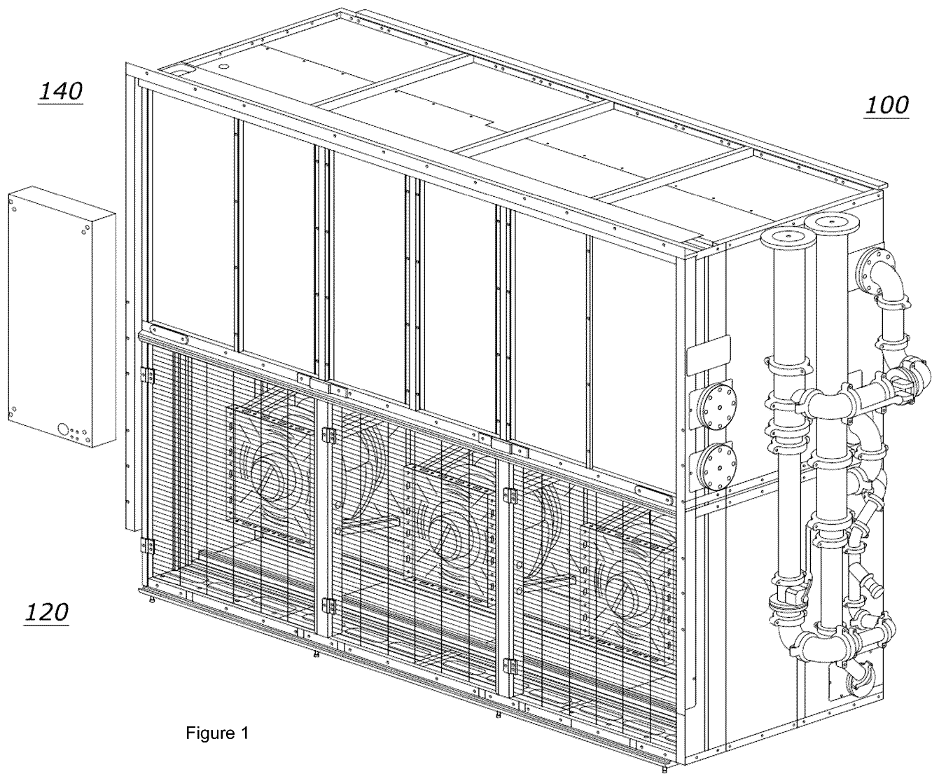

FIG. 1 illustrates a perspective view of a block diagram of an embodiment of an example integrated liquid and air cooling unit that has a framework structured to contain and support a weight of one or more air-based cooling modules and one or more direct liquid cooling modules, in the same real estate space/footprint, to supply the air-based cooling and the direct liquid cooling to the Information Technology (IT) computing equipment housed in a datacenter. The integrated liquid and air cooling unit 100 with one or more air-based cooling modules 120 (also referred to as fan coil wall or fan coil module), one or more direct liquid cooling modules 140 (also referred to as Cooling Distribution Unit “CDU”), and any combination of these, allows the datacenter to have both liquid and air-based cooling in the same footprint (e.g., integrated unit) rather than need separate disparate spaces; and thus, separate real estate spaces within the datacenter for the two different cooling modalities. The integrated liquid and air cooling unit 100 has a framework constructed to contain and support the weight of the one or more air-based cooling modules 120 and the one or more direct liquid cooling modules 140, in the same real estate space, to supply air-based cooling as well as direct liquid cooling to the IT computing equipment housed in the datacenter. The example integrated liquid and air cooling unit 100 shown has one air-based cooling module 120 that has one direct liquid cooling module 140 stacked on top of the air-based cooling module.

The framework of the integrated liquid and air cooling unit 100 can put the direct liquid cooling module 140 on the top layer of the framework, on the bottom layer of the framework, and/or in the middle layer of the framework as long as the mixture has one or more direct liquid cooling modules 140 and one or more air-based cooling modules 120.

The framework structure can be made of structural steel, such as 14 gage galvanized steel, reinforced with quarter inch hot dipped galvanized steel brackets at all the lifting points where the flanges have reinforcements at the top and bottom lifting points for each module. The frame and structure of a cabinetry of the integrated liquid and air cooling unit 100 are designed to accommodate the weight of each mechanical cooling module stacked on top of another mechanical cooling module. Thus, the frame and structure of a cabinetry of the integrated liquid and air cooling unit 100 are constructed to accommodate a weight of 1) a first air-based cooling module 120 or a first direct liquid cooling module 140 stacked on top of 2) a second air-based cooling module 120 or a second direct liquid cooling module 140.

The integrated liquid and air cooling unit 100 has the framework to integrate an associated electrical panel and a common piping manifold.

The integrated liquid and air cooling unit 100 has an associated electrical panel that can be installed on the side of the integrated liquid and air cooling unit 100 or on a stanchion or a wall nearby the integrated air and cooling unit.

The integrated liquid and air cooling unit 100 also has a common piping manifold installed on the integrated liquid and air cooling unit 100 that connects to the facility cooling water to supply cooling fluid (e.g. chilled water) and accept a return of heated fluid from an air coil in the air-based cooling module 120 and a heat exchanger in the direct liquid cooling module 140 in order to reject heat out of the datacenter and the IT computing equipment housed within the datacenter.

The frame and structure of a cabinetry of the integrated liquid and air cooling unit 100 is constructed to allow either air-based cooling module 120 or direct liquid cooling module 140 to slide into the same designed space of the framework and mechanically connect up to the same facility water connections. Thus, each air-based cooling module 120 and direct liquid based cooling module is designed to have its internal piping slide in and mate up to the piping connections provided by the piping manifold. Each air-based cooling module 120 and each direct liquid cooling module 140 has substantially, within an inch, the same width and depth dimensions, the same facility water connections, similar electrical connections into the electrical panel supplying electricity for that module, and the same framework, such that a direct liquid cooling module 140 can be swapped with the air-based cooling module 120 in the same designed space of the framework, and vice versa.

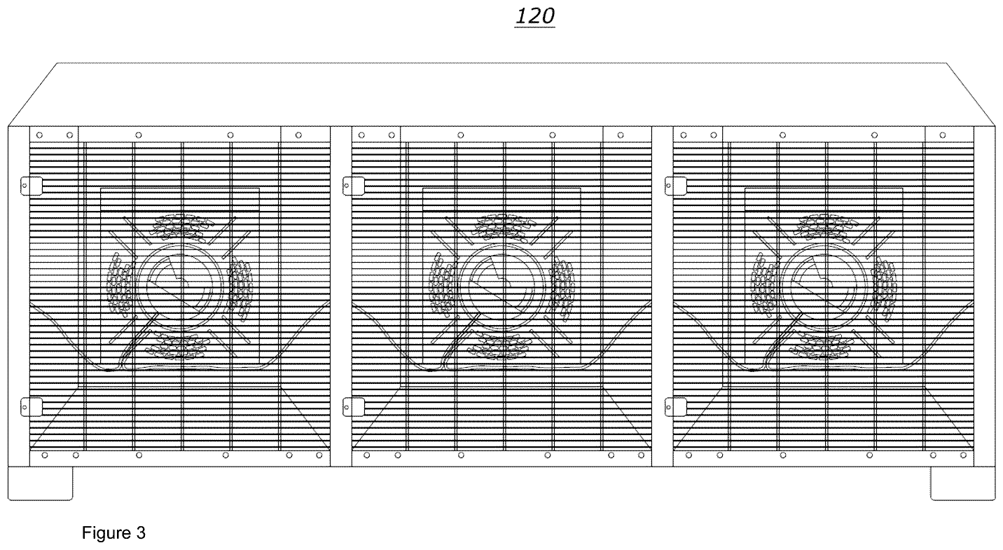

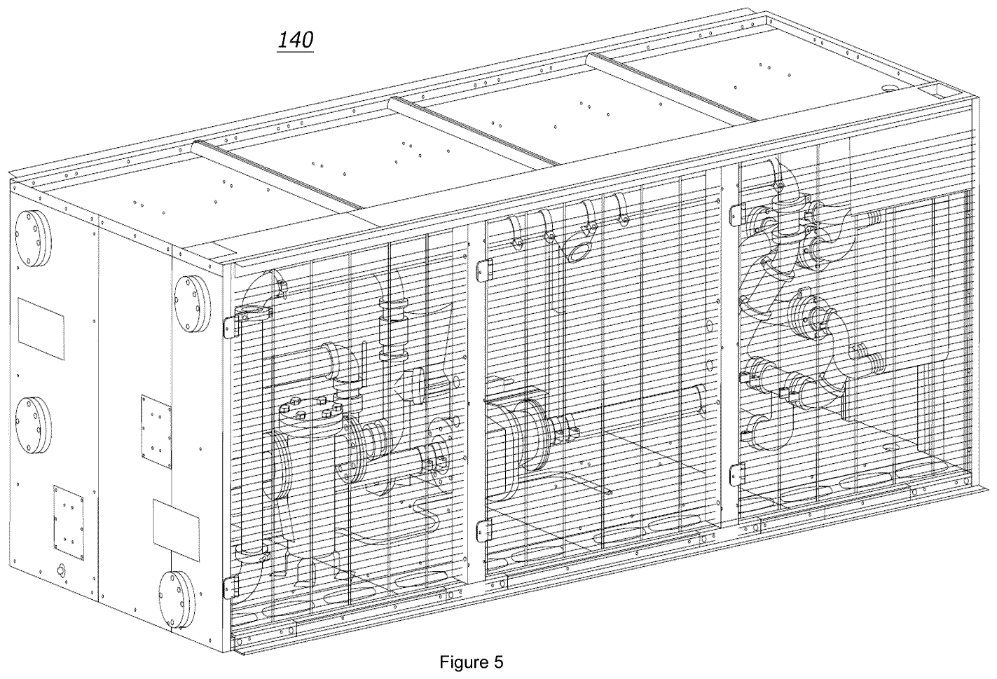

Each mechanical cooling module, e.g. direct liquid cooling module 140 and/or air-based cooling module 120, in the integrated liquid and air cooling unit 100 is constructed to be integrated and bolted together in the same stack with another direct liquid cooling module 140 and/or air-based cooling module 120 in the integrated liquid and air cooling unit 100, as well as be unbolted to come apart in order to change out, for example, the air-based cooling module 120 for a direct liquid cooling module 140 in order to switch a cooling modality of the datacenter over a lifetime of the datacenter. Thus, the integrated liquid and air cooling unit 100 is constructed to be able to change out the different mechanical cooling modules; and thus, cooling modalities as the current needs of the datacenter requires. Each mechanical cooling module (See for example FIG. 3 and FIG. 5) can be made so that a lower and an upper module can be bolted together using, for example, half inch bolts that are two inches long as well as the upper and lower module will typically have a cell form gasket inserted between the two modules to form an airtight seal. All welds can be coated with zinc oxide to prevent corrosion. Each mechanical cooling module can also have its own isolation valve so that it can be taken offline and maintained without interrupting its neighboring modules in the same stack and corresponding IT computing equipment.

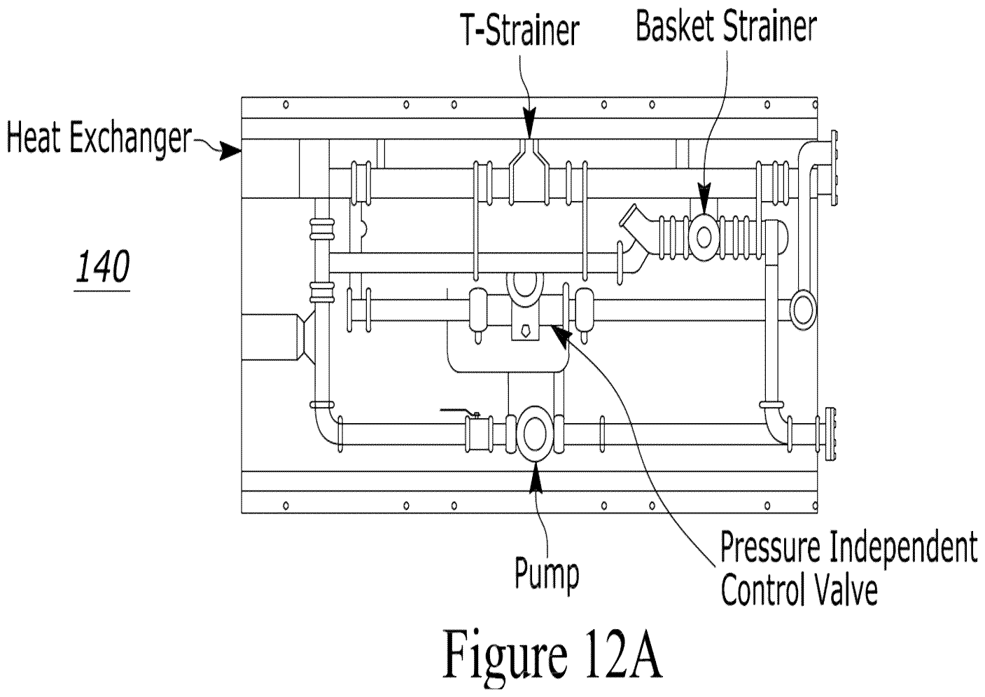

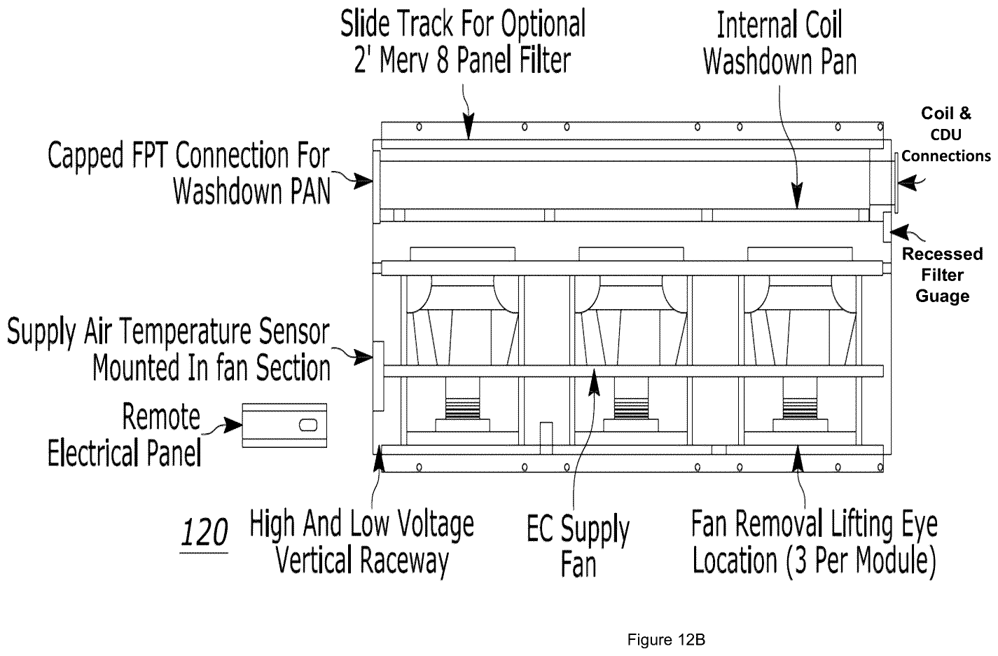

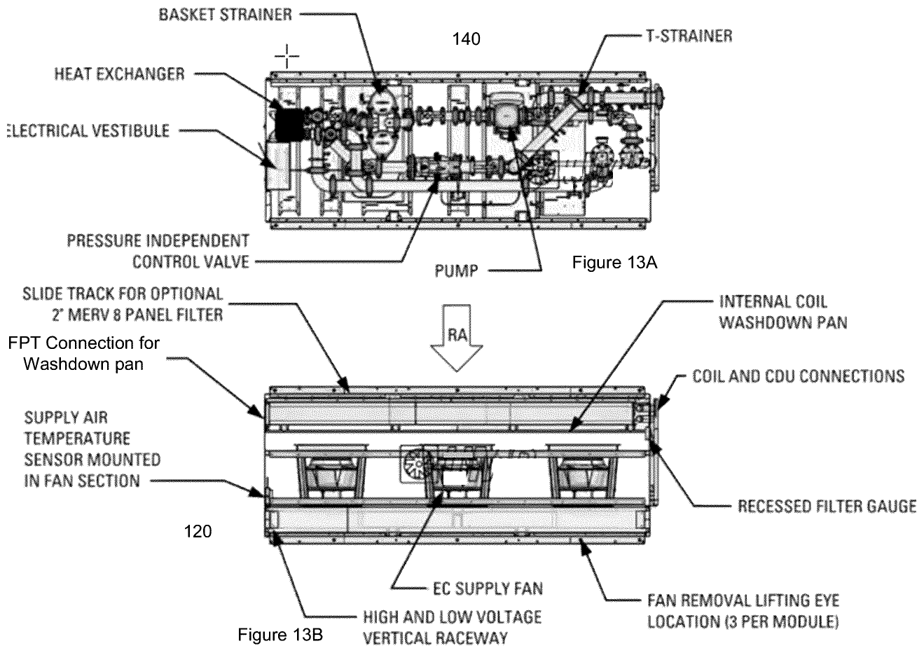

The integrated nature of the integrated liquid and air cooling unit 100 has the different mechanical cooling modules, e.g., air-based cooling modules 120 and direct liquid cooling modules 140, with different internal components inside those mechanical cooling modules (see FIGS. 12A, 12B, 13A, and 13B), but each mechanical cooling module has essentially the same width and depth dimensions, same facility water connections, similar electrical connections into the electrical panel supplying electricity for that module, and the same framework, such that you can swap in a direct liquid cooling module 140 with an air-based cooling module, and vice versa. Thus, the frame is constructed as a mechanical weight support structure with the same mechanical water connections for the modules to slide into the designed spaces in the frame such that either an air-based cooling module 120 or a direct liquid cooling module 140 can plug into the framework of the integrated liquid and air cooling unit 100.

The framework with its mechanical structure, cooling piping manifold, and an electrical power panel is designed to be able to switch over from an installed air-based cooling module 120 installed in a first space of the framework over to a direct liquid cooling module 140 installed in the first space of the framework without having to take everything apart and recommission the electrical, mechanical, and structural requirements of an initially installed integrated liquid and air cooling unit 100. An air-based cooling module 120 is designed with the facility piping connections and electrical connections in roughly the same place as a direct liquid cooling module 140 so that either module can be taken out and literally slides in an air-based cooling module 120 or direct liquid cooling module 140 to marries up to the existing facility connections in the integrated liquid and air cooling unit 100. The framework of the integrated liquid and air cooling unit 100 with its mechanical structure, cooling piping manifold, and electrical power panel arrangement is designed for interchangeability between an air-based cooling module 120 and a direct liquid cooling module. The pipe diameter can be chosen to be able to supply a maximum flow rate needed to remove the heat from, if all the spaces for modules in the integrated liquid and air cooling unit 100 were direct liquid cooling modules 140. Thus, the pipe diameter is chosen to be able to supply a maximum flow rate from the chilled water system needed to remove the heat from the maximum/highest heat load from the modules making up the integrated liquid and air cooling unit 100. Thus, the piping from the facility water can remove, for example, 500 kW of heat load for a given module position even if merely a 250 KW air based cooling module is installed currently in that position. In instances where the approach temperature is expanded, the direct liquid cooling modules' 140 capacity can be improved from its nominal rating of 500 kW. With the current heat exchanger, the direct liquid cooling modules 140 can deliver as much as 618 kW. Indeed, depending on heat exchanger selection and application conditions (in particular deltaT and approach temperature) additional cooling capacity can be derived.

Next, the data hall with its multiple rows of racks of IT computing equipment is air cooled by the air-based cooling module, which increases or decreases the flow rate of air for all of the rows of IT computing equipment being cooled by the air-based cooling module 120 based upon sensed pressure differential across the Hot Aisle Containment System (HACS). The air-based cooling module 120 modulates the flow of facility chilled water through its cooling coil using the pressure independent control valve (PICV) that is mounted to the piping manifold, thus transferring heat from the air stream to the facility water. The modulating PICV is controlled by the air based cooling module's control system based on sensed leaving air temperature of the air based cooling module 120 The direct liquid cooling module 140 cools internally individual IT computing equipment that is designed to be liquid cooled in each row of IT computing equipment.

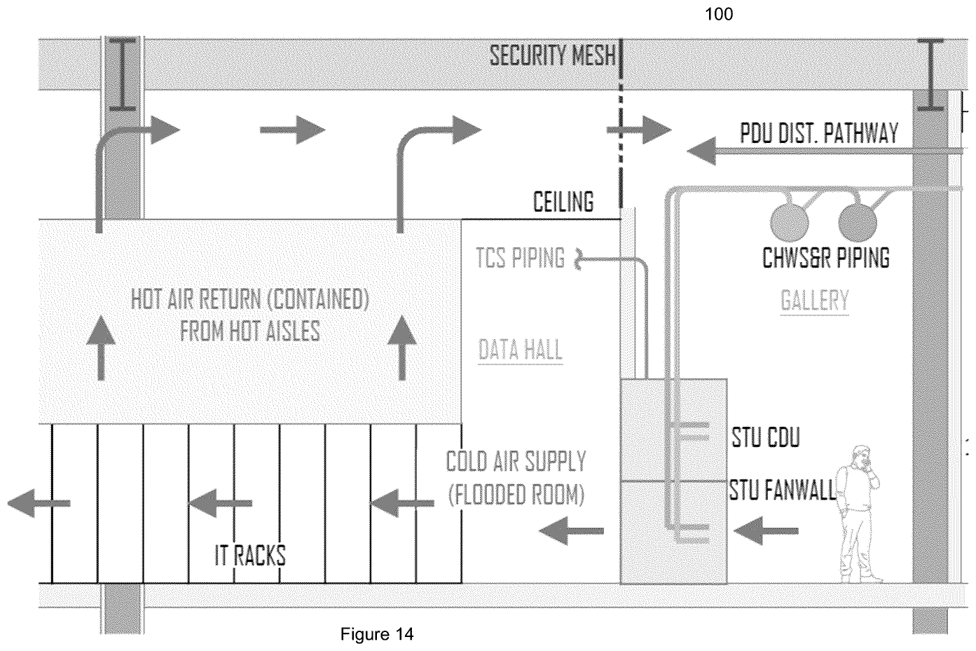

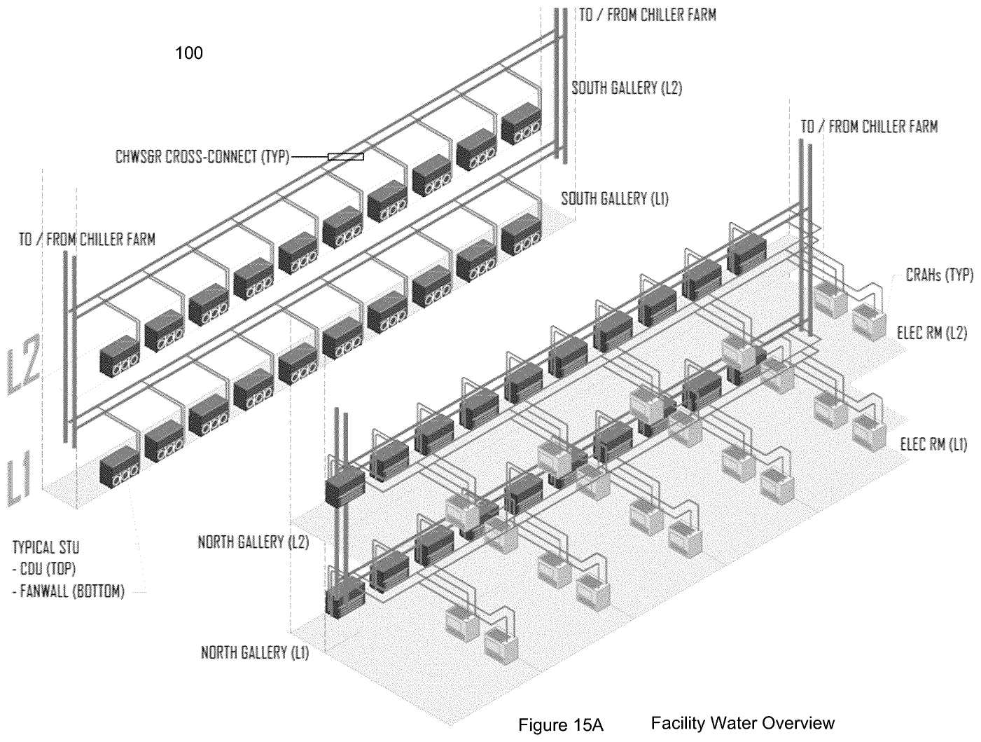

FIG. 14 illustrates an example cross sectional elevation building layout block diagram of a data hall with air flow and liquid cooling utilizing an embodiment of an example integrated liquid and air cooling unit 100.

Again, the air-based cooling modules 120 can increase or decrease the flow rate of air for all of the rows of IT computing equipment being cooled by the air-based cooling module 120 based upon sensed return temperature. The fans can all modulate up and down according to the pressure differential across the data hall containment systems. The fans can support the whole data hall and all of the IT computing equipment; whereas, the direct liquid cooling module 140 controls, generally, one or more zones within the multiple rows of IT computing equipment that specifically use direct liquid cooling.

In a 2 megawatt zone of an 8 megawatt data hall, some of the racks may be air cooled and some of the racks may be direct liquid cooled. Each direct liquid cooling module 140 nominally cools up to 500 KW of heat load so a two megawatt zone will have four direct liquid cooling modules 140 cooling that zone and then one direct liquid cooling module 140 acting as redundancy back up cooling for the entire set of zones in, for example, an eight megawatt datacenter.

Next, the datacenter contains 1) racks of IT computing equipment-including servers, storage, switches, routers, etc.; 2) an electrical distribution system including uninterruptible power supply (UPS) batteries; and 3) a heat rejection/ventilation/air-conditioning (HVAC) system. The datacenter can accommodate any design of racks of IT computing equipment that include servers, storage, switches, etc. of varying size and manufacturer. The datacenter at day one may have an initial set of IT computing equipment, such as servers and other Information Technology rack equipment, which has a heat load needing ‘X’ amount of kW of heat to be removed. Yet, the datacenter in the future may have different set of servers and other Information Technology rack equipment that has a heat load needing ‘Y’ amount of kW of heat to be removed and/or need a different cooling medium-direct liquid cooling versus air-based cooling. The frame and structure of the integrated liquid and air cooling unit 100 are constructed with 1) the common piping manifold integrated onto the integrated liquid and air cooling unit 100, 2) the electrical power panel, and the 3) cabinetry to slide either module into a same designed space in the framework to allow this interchangeability. All of the cooling is supplied from the same framework to cool the building's IT computing equipment, which has a potential mixture of IT computing equipment needing i) direct liquid cooling and then other IT computing equipment needing ii) to remove heat from the air space around the IT computing equipment.

The integrated liquid and air cooling unit 100 supports various mixtures of ratios of air-based cooling modules 120 and direct liquid cooling modules 140 installed in the integrated liquid and air cooling unit 100 to support the air-based and liquid based IT equipment cooling needs of IT equipment in the datacenter. The integrated liquid and air cooling unit 100 is constructed such that a first ratio of air-based cooling modules 120 compared to direct liquid cooling modules 140 installed on the integrated liquid and air cooling unit 100, on day one of an operation of the datacenter, and then be configurable to have a second ratio of air-based cooling modules 120 compared to direct liquid cooling modules 140 installed on the integrated liquid and air cooling unit 100, at a later day of an operation than day one of the datacenter, in order to supply a different heat removal need of the IT computing equipment in a future operation of the datacenter.

The integrated liquid and air cooling unit 100 can reduce the overall size occupied in a datacenter because the integrated liquid and air cooling unit 100 has both cooling modalities in the same real estate as well as offers more cooling/heat rejection capacity in the same footprint. The integrated liquid and air cooling unit 100 allows for the provisioning of direct liquid cooling modules 140 (e.g., Cooling Distribution Units) integrated with air-based cooling modules 120 in the same footprint as prior fan cooling units.

Also, in the same real estate space and location within a datacenter, this integrated liquid and air cooling unit 100 is able to give the datacenter one modality of cooling today, a different mode of cooling tomorrow, and/or a different variation or ratio of one mode to the different mode without having to change the facility chilled water piping connections to the integrated liquid and air cooling unit 100 and/or obtain additional certifications. The integrated liquid and air cooling unit 100 for a datacenter gives the configurability and flexibility to provide different types of cooling depending upon the datacenter's needs at that time which can be configured to provide a different type of cooling at a subsequent time. The integrated liquid and air-cooling unit 100 provides the datacenter a variable cooling/heat rejection option both at day one and when the combination of IT computing equipment housed in the datacenter results in a denser scenario of more direct liquid cooled IT computing equipment that needs a higher amount of heat removal in the future. The ratio of customer installed IT computing equipment in the data hall of the datacenter may change from time/day one of, for example, 30 or 40% of the IT computing equipment being direct liquid cooled and then the rest being air cooled over to, for example, time/day two thousand-60% or 70% of the IT computing equipment being direct liquid cooled and then the rest being air cooled with the same integrated liquid and air cooling unit 100 supplying those cooling needs. Although, the same integrated liquid and air cooling unit 100 supplies those cooling needs with a different make up of the number of air-based cooling modules 120 and direct liquid cooling modules 140 installed in that integrated liquid and air cooling unit 100.

Thus, as an amount of IT computing equipment that is designed to be cooled via air changes to being cooled by direct liquid contact in the data center, then the framework with its 1) common piping manifold, 2) the electrical power panel arrangement, and 3) cabinetry is constructed to allow the easy removal of an air-based cooling module 120 and the insertion of a direct liquid cooling module, or vice versa.

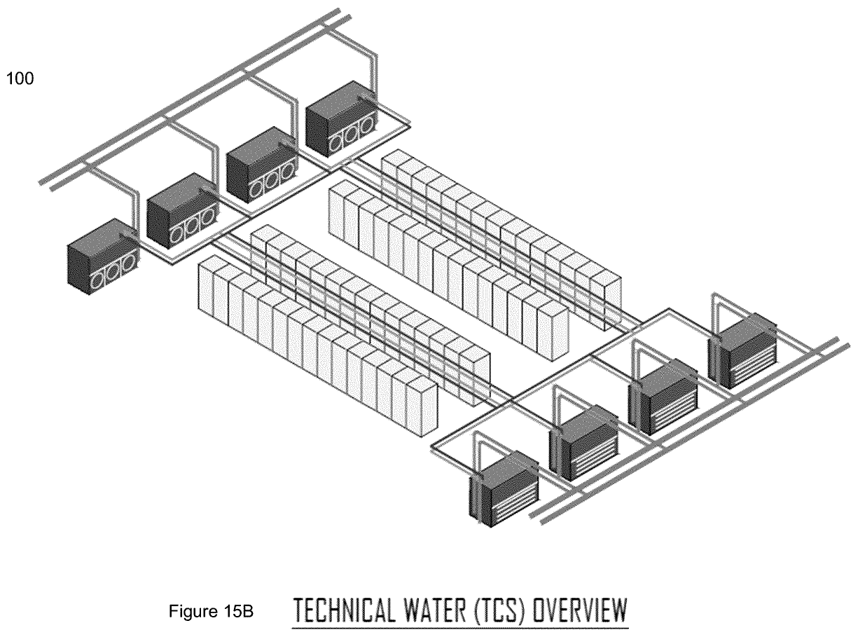

FIG. 15A illustrates an example isometric view of data halls (on two building levels) with air flow and liquid cooling utilizing an embodiment of an example integrated liquid and air cooling unit 100.

The datacenter facility can easily change out the heat rejection type (air cooling or liquid cooling types) and add capacity from IT computing equipment in a datacenter through air and/or liquid modalities that can provide one or more air-based cooling modules 120, one or more direct liquid cooling modules 140, and any combination of these. This mix of air cooling, liquid cooling, and overall capacity of cooling/heat rejection can be changed with minor maintenance of changing out modules over the life of the operation of the datacenter without having to shut down an operation of the IT equipment in the datacenter. Also, the datacenter can swap out air-based cooling modules 120 and/or direct liquid cooling modules 140 of capacity and not have to create new real estate in the datacenter to accommodate the new heat rejection/cooling equipment. The datacenter can add and/or subtract liquid cooling capacity and air cooling capacity as the needs dictate at that time of operation of the datacenter.

Likewise, 1000 kilowatts of direct liquid cooling modules 140 can fit in the same footprint as 500 kilowatts of air-based cooling modules 120. Thus, the integrated liquid and air cooling unit 100 provisions a modular datacenter cooling system that allows varying combinations of direct liquid cooling IT equipment and air cooled IT computing equipment. The integrated liquid and air cooling unit 100 provides the flexibility of not having to decide what cooling modality a datacenter will provide today. The datacenter has the ability now to flex whatever density and cooling modality that the datacenter needs to put in place today while having the flexibility to put in different combinations of modules in the future with the integrated liquid and air cooling unit 100.

The integrated liquid and air cooling unit 100 can take several forms based on how it is provisioned with ratios from—100% air-based cooling only (air-based cooling modules 120), 0% air-cooling with 100% direct liquid cooling modules 140, and combinations of each type of module 120, 140, which allows for any mix of air-based cooling and direct liquid cooling in the Data Hall of the datacenter.

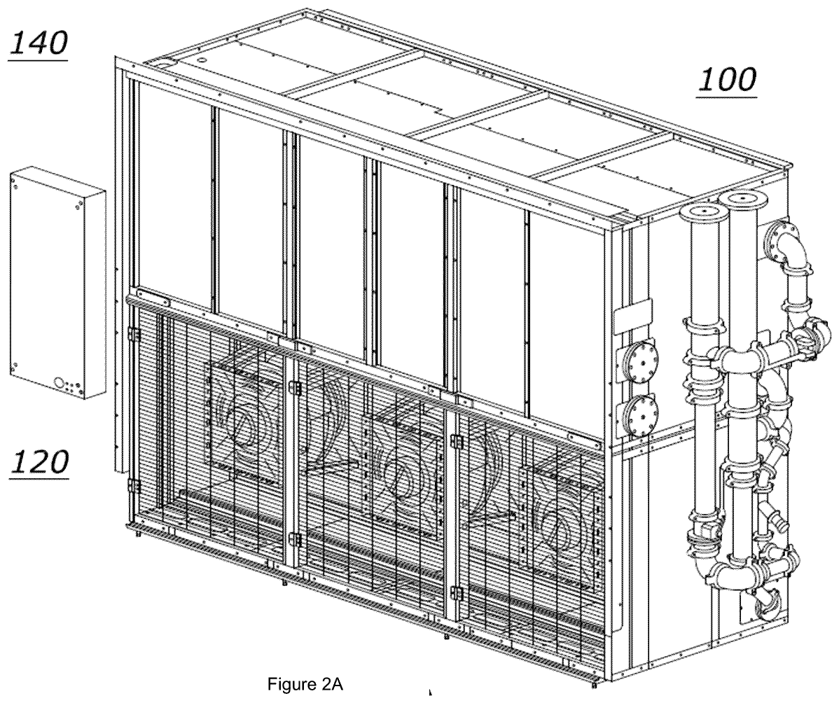

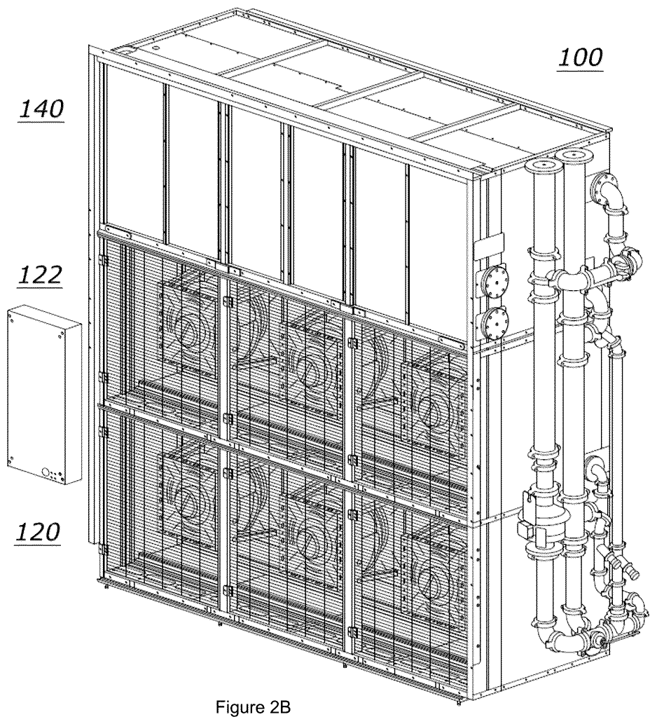

FIG. 2A illustrates a perspective view of a block diagram of an embodiment of an example integrated liquid and air cooling unit that has a single direct liquid cooling module stacked on top of a single air-based cooling module. An example stack of one air-based cooling module 120 and one direct liquid cooling module 140 is shown.

FIG. 2B illustrates a perspective view of a block diagram of an embodiment of an example integrated liquid and air cooling unit that has a single direct liquid cooling module stacked on top of two air-based cooling modules. An example stack of two air-based cooling modules 120, 122 and one direct liquid cooling module 140 is shown. The integrated liquid and air cooling unit 100 can include two or more direct liquid cooling modules 140 and one or more air-based cooling modules 120.

As discussed, the framework is constructed to let the modules sit/stack on top of each other.

The integrated liquid and air cooling unit 100 further has two or more controllers installed and associated with the air-based cooling modules 120 and the direct liquid cooling modules 140 that are configured to allow bifurcated temperature zones in a sense that 1) a first controller is programmed to control and operate a first air-based cooling module 120 to supply cooling to maintain a first example temperature set point for IT computing equipment and/or the datacenter itself being cooled by the first air-based cooling module 120 and 2) a second controller is programmed to control and operate a first direct liquid cooling module 140 to supply cooling to maintain a second example temperature set point for IT computing equipment being cooled by the first direct liquid cooling module, and then both take advantage of the increased amount of economization that comes with. IT computing equipment that can use liquid cooling can typically operate at a higher temperature and/or operational range of temperature set points compared to IT computing equipment that uses air-based cooling. With the provisioning of a single facility water piping network, this system can accommodate data hall air temperatures typical in today's standards, while also allowing for direct liquid cooling at lower temperatures. Note, by provisioning two facility water piping networks, the system can deliver the same air conditions as before, while driving up the second facility water source to much higher temperatures, thus realizing the full efficiency benefits promised by direct liquid cooling. In addition, the electrical and software controls for the integrated liquid and air cooling unit 100 come in their own casing and box that can be readily attached to the integrated liquid and air cooling unit 100 or connected up remotely to the integrated liquid and air cooling unit 100 depending upon if the operating temperature of the integrated liquid and air cooling unit 100 is above a temperature that could affect the operation of the electronics inside the casing of the electrical and software controls for the integrated liquid and air cooling unit 100.

The piping manifold supplies water to the pressure independent control valve and then to the air coil in the air-based cooling module. The pressure independent control valve controls flow of facility chilled water to the air coil, which the fans then draw data center air through the air coil. One pressure valve in the piping manifold can supply and control water flow of cooling water to fan coils in multiple air-based cooling modules 120 and just operate as though they are basically one air-based cooling module 120 with a combined heat load output that needs to be rejected.

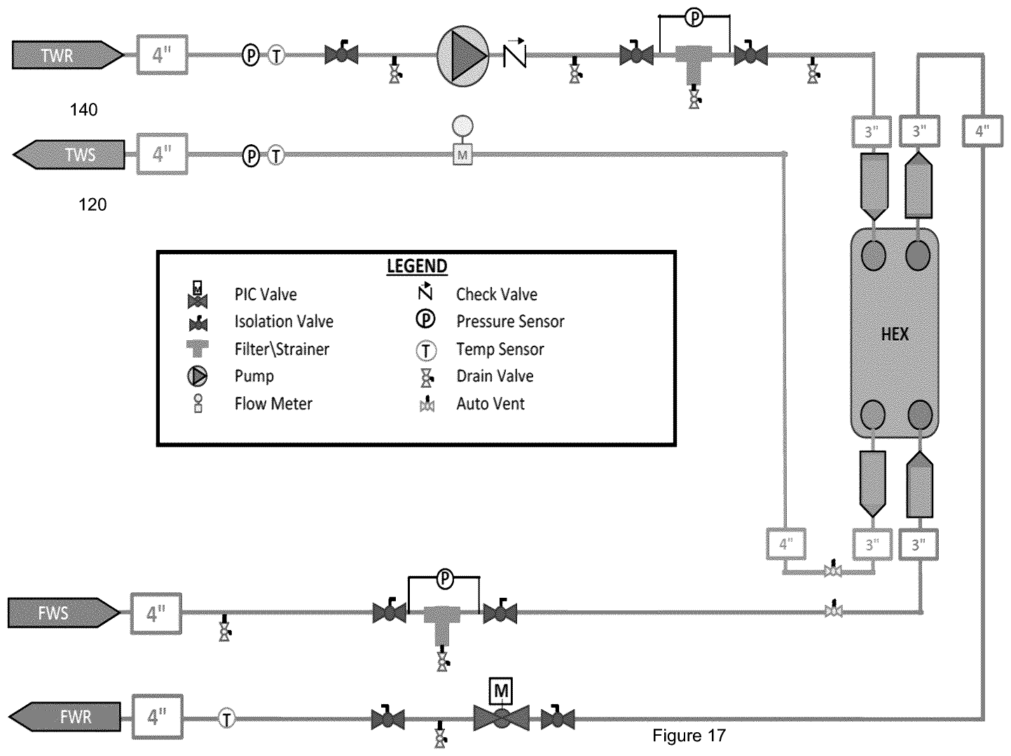

Each module 120 and 140 of the integrated liquid and air-cooling unit can be also given its own pressure independent control valve/flow control valve to control the amount of heat that is being transported from that module (e.g., air-based cooling module 120 or direct liquid cooling module). The pressure independent control valve/flow control valve modulates its position so as to maintain the leaving facility cooling fluid temperature setpoint, such that a desired Delta T, such as a Delta T of 14 degrees Fahrenheit, is maintained. As depicted in FIG. 17, each module 120 and 140 has supply water temperature sensed by a sensor on the technology cooling fluid leaving side and facility cooling fluid temperature sensed by sensors on the facility cooling fluid entering and leavings sides, and the flow rates and the Delta Ts are aligned for the amount of heat that is being rejected.

Again, facility water supply in the piping manifold can be selected to supply a maximum anticipated heat removal needed in a future of the datacenter. For example, the piping manifold can be sized to be capable of transporting 1000 kW of heat per integrated liquid and air-cooling unit position.

At generally accepted upper range fluid velocities, a 4-inch pipe can supply a row of IT computing equipment a flow rate of 320 gallons per minute which, given a deltaT of 10 Degree Celsius can transport up to 800 kilowatts of heat out. An example 6-inch row header supply to the row of IT computing equipment with a flow rate of 680 gallons per minute and deltaT of 10 Degrees Celsius can transport up to 1700 kilowatts of heat out. An example 10-inch row header supply to the row of IT computing equipment with a flow rate of at 1600 gallons per minute and deltaT of 10 Degrees Celsius can transport up to 2750 kilowatts of heat out.

FIG. 3 illustrates a frontal view of a block diagram of an embodiment of an example air-based cooling module with a set of three fans and an associated air coil. The air-based cooling module 120 can have its own casing, a set of two or more fans, an air coil, an air filter, and a pressure control modulating valve located on an outside frame of the first air-based cooling module 120 as part of a piping manifold.

Each air-based cooling module 120 and/or direct liquid cooling module 140 has its own casing and structural steel, such as 14 gage galvanized steel, with the same width and depth dimensions matching another module whether that be air-based or liquid cooling to house the components of that module. Again, the framework is made strong enough so that it can handle either pumps providing liquid cooling or fans supplying air cooling and then be slid into a housing space for that module in the framework of the integrated liquid and air cooling unit 100. The piping connections are all in the same location allows modularity and swapability between the different types of modules. An air-based cooling module 120 in a particular housing space section of the framework can be swapped out with the direct liquid cooling module 140 in that same particular housing space section of the framework, and vice versa.

Each air-based cooling module 120 is provided with a recessed differential pressure filter gauge for visual filter pressure drop indication of the for example the twelve 24″×24″ filters installed in the air-based cooling module. An embodiment of a taller air-based cooling module 120 can include an additional six 12″×24″ filters stacked on the twelve 24″×24″ filters. Each supply fan can be a direct-drive, centrifugal fans with integrated control electronics.

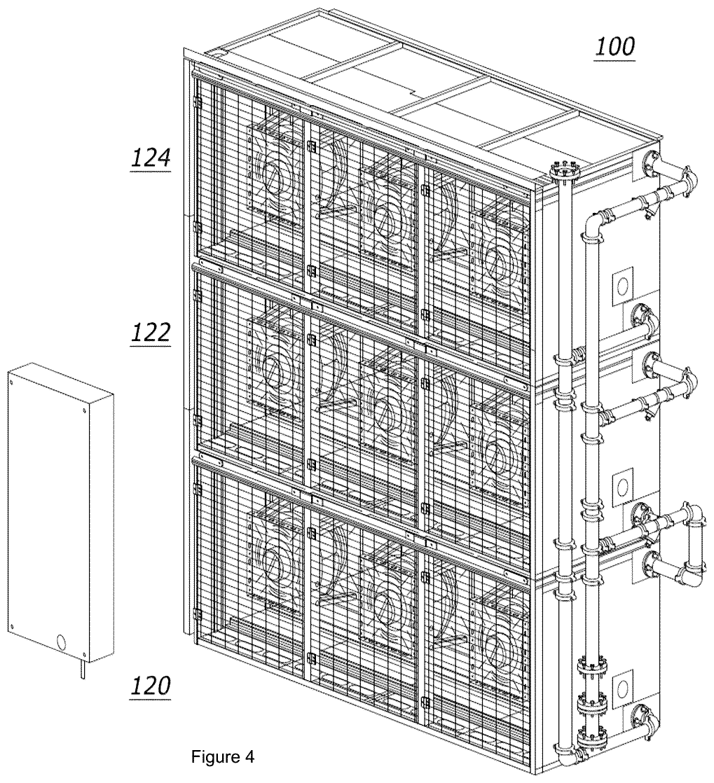

FIG. 4 illustrates a perspective view of a block diagram of an embodiment of an example integrated liquid and air-cooling unit that has three air-based cooling modules stacked on top of each other. A stack of three example air-based cooling modules 120, 122, 124 is shown with a common piping manifold, controlled by a single modulating pressure independent flow control valve to supply and return facility water.

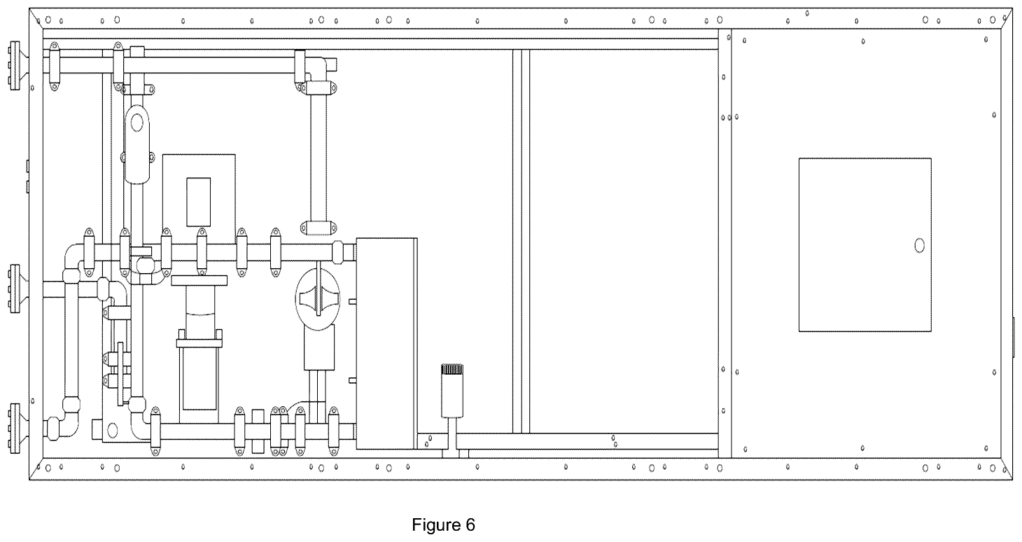

FIG. 5 illustrates a perspective view of a block diagram of an embodiment of an example direct liquid cooling module that has its own casing and internal components including a heat exchanger, a T-strainer, a dual capacity basket strainer and bag filter, a pump, leak detection, a pressure independent control valve, pressure and flow sensors and its own controller. FIG. 6 illustrates a frontal view of a block diagram of an embodiment of an example direct liquid cooling module with the heat exchanger, the T-strainer, the filter, the pump, sensors, and the pressure independent control valve that can be configured to not be able to close completely. The direct liquid cooling module 140 cools, distributes, and regulates a cooling fluid within a liquid cooling system (typically referred to as a Technology Cooling System “TCS” in a liquid cooling system in a datacenter). The direct liquid cooling module 140 is used in this cooling system to distribute coolant, such as water or other fluids, to different parts of the IT computing equipment that require liquid cooling. The IT computing equipment receives the cooling lines from the direct liquid cooling module 140 and routes that cooling fluid internally in the IT computing equipment to remove the heat from within the IT computing equipment and then return the warm cooling fluid back to the direct liquid cooling module 140 where a heat exchanger transfers the heat from the TCS fluid to the facility side cooling fluid, which returns into the building's chilled water or other cooling water system. Thus, each direct liquid cooling module 140 regulates the temperature in the IT equipment by transporting heat out of the IT computing equipment located in the datacenter's whitespace and transfers that heat to the facility's water system (often referred to as the plant or chilled water system where chillers are utilized).

FIG. 15B illustrates an example cross isometric view of a data hall Technical Water System (also commonly referred to as Technology Cooling System or TCS) utilizing an embodiment of an example integrated liquid and air cooling unit 100.

A controller programmed with operational logic combined with smart controls and manage IT computing equipment (e.g., server) and datacenter cooling system performance. Smart controls respond to peak demands while remaining economical and efficient during non-peak operation and prevent problems before they occur. The piping manifold supplies water to the pressure independent control valve internally in the direct liquid cooling module. Each of those direct liquid cooling module 140 are given a pump signal, according to the pressure in the loop, and the amount of flow that is flowing through the loop. So, depending on the pressure drop, how many racks are plugged in, then the pump will modulate up and down according to that pressure set point, and then the controller makes sure that it is matching the right amount of flow according to the right amount of heat power being rejected out of that IT computing equipment technology cooling water loop. So, the modulating flow control valves in each direct liquid cooling module 140 are not really dependent on each other. Note, however, the pressure independent control valve for the air coils in the air-based cooling modules 120 modulates open or closed according to the supply air temperature delivered to the cold aisle directly in front of the racks of IT computing equipment being cooled to keep the overall efficiency of the chilled water facility up and open up and let more water through to increase cooling capacity or close down and reduce the amount of water going through the air coils to reduce cooling capacity. This is done to optimize the flow and temperature in the system and keep the chilled water plant staged for best possible efficiency.

The direct liquid cooling module 140 can have a heat exchanger, a pump, and a pressure independent control valve to modulate facility chilled water flow. The pressure independent control valve can be configured to not be able to close completely; and thus, always allow a defined minimum facility chilled water flow to move through the pressure independent control valve and heat exchanger. In the event that there is a sudden increase in IT heat output from a particular type of IT computing equipment (e.g., a particular server), which the pressure independent control valve's actuator could not respond to quick enough, allowing a minimum flow through the pressure independent control valve and heat exchanger will reduce the amplitude of any temperature spike. This type of IT computing equipment has its heat load ramp up within milliseconds out of nowhere so the direct liquid cooling side if completely closed could not open quickly enough to recover to keep temperature within that individual server within its operating limits. Instead, the pressure independent control valve can be configured to have allow facility chilled water to flow through the heat exchanger even if the temperature of the Technology cooling water returning from the IT computing equipment has not increased. In this instance the pressure independent control valve is allowing facility chilled water to flow, regardless of whether it is picking up heat or not, just because we know that this type of IT computing equipment (e.g., a liquid cooled server) can ramp up its power output faster than the control valve can respond. The controller working with the pressure independent control valve works to reduce the rate that the heat rise occurs. The controller working with the pressure independent control valve can slow the rate of temperature change in the technical cooling system by opening the control valve and flooding the heat exchanger thereby increasing the heat flow out of the Technology Cooling water and heat exchanger. As the controller working with the pressure independent control valve senses that rate of change of heat to start to rise, the valve actuator can respond in time to increase its opening and supply more cooling water to the heat exchanger thus rejecting the added heat being generated within the corresponding connected IT equipment.

Each direct liquid cooling module 140 has its own programmable logic controller and its own electrical panel. The programmable logic controller for the direct liquid cooling module 140 can control its corresponding pump and pressure independent control valve due to the rapid heating possibility of an IT computing equipment being serviced by the direct liquid cooling module.

Different master controllers, e.g. a programmable logic controller, can be used, one master controller for the air-based cooling modules 120 and one master controller for the direct liquid cooling modules 140.

Referring back to FIG. 2B, the master controller feeds 1, 2 or 3 air-based cooling modules 120 which when connected the master controller the air-based cooling modules 120 can behave as a single air-based cooling module to handle the combined heat load. Likewise, there can be a single master controller for multiple direct liquid cooling modules 140, which can behave as a single direct liquid cooling module to handle the combined heat load. The master controller for the air-based cooling modules 120 can control 3 fans, 6 fans, or 9 fans depending upon how many air-based cooling modules 120 are installed on the integrated liquid and air-cooling unit. Again, two separate master controllers allow the direct liquid cooling modules 140 to operate with a different operating temperature for cooling than the air-based cooling modules 120, and having separate master controllers makes it very easy to have different operating temperature set points for air-based and direct liquid cooling-based IT equipment.

FIG. 12A illustrates a top-down view of a diagram of an embodiment of an example a direct liquid cooling module that has its own casing and internal components including a heat exchanger, a T-strainer, a dual capacity basket strainer and bag filter, a pump, leak detection and pressure and flow sensors, as necessary. The direct liquid cooling module 140 can have its own casing and internal components including a heat exchanger, an electrical vestibule, a dual capacity basket strainer and bag filter, a T-strainer, a pump, a pressure independent control valve, pressure and flow sensors and its own programmable logic controller, and its own electrical power panel.

Each direct liquid cooling module 140 has its own Facility Chilled Water filter screen connected in line upstream of the heat exchange, so that the heat exchanger in the direct liquid cooling module 140 remains clean and effective Also, there are differential pressure sensors monitoring the pressure drop across the screen and will indicate when the filter screen is beginning to become loaded with particulate.

Since the galleries in the IT equipment cooling components are as small as 100 microns in diameter (0.1 mm or 0.003937 in) they are susceptible to blockage with any particulate over 50 microns (0.05 mm or 0.001969) in diameter. Thus, the filter selected for the technology cooling side of the direct liquid cooling module 140 is designed to filter out particles down to 25 microns (0.025 mm or 0.000984 in). It has a large dirt holding capacity and high flow rate capability, which results in a low pressure drop across the filter even when experiencing some particulate loading, thereby virtually eliminating the chance of a reduction in flow to the critical IT equipment.

The dual capacity basket strainer and bag filter is used on the Technology cooling side for the IT computing equipment. The dual capacity basket strainer and bag filter provides really clean, hyper pure, cooling fluid (e.g. typically a mixture of water and 25% polyethylene glycol, but in some cases pure water with biocidal inhibitors) that goes through the TCS pipes directly to the chips and the cold plates internal in the IT computing equipment themselves. An embodiment of the direct liquid cooling module 140 can have its own casing and internal components including a heat exchanger, a T-strainer, a dual capacity basket strainer and bag filter, leak detection and a pump, where the dual capacity basket strainer and bag filter is used on an internal Technology cooling side for the IT computing equipment being cooled by the first direct liquid cooling module. The dual capacity basket strainer and bag filter can be located between the pump and the heat exchanger. These dual capacity basket strainer and bag filter have long microscopic bag filters, e.g., 32″ about twice the length of a standard filter bag, to clean out anything that is bigger than 25 microns. The reason is the cold plates that sit on the processors in the CPU and GPUs of the IT computing equipment, which have 100 micron galleries/piping, so the size of the little holes in these cold plates that the fluid goes through and picks up all that heat is only 100 microns in diameter. So, the parallel T strainers filter down to particles that are ¼th of that diameter e.g., filtering down to 25 microns, to filter out contamination in the technology cooling fluid water to prevent potentially plugging up all these cold plates on billions of dollars' worth of IT hardware.

Note, a 25 micron filter by itself may not cut it and instead needs a combo of a 25 micron strainer with an extended bag filter with a significantly larger surface area to collect contaminants before plugging up. The dual capacity basket strainer and bag filter includes a tremendous amount of surface area, and a sensor to indicate when the dual capacity basket strainer and bag filter is becoming clogged. The dual capacity basket strainer and bag filter with a large surface area filter bag help to mitigate contamination events and prevent contamination spreading through the system.

FIG. 12B illustrates a top-down view of a diagram of an embodiment of an example an air-based cooling module that has its own casing, a set of two or more fans, an air coil, an air filter. The air-based cooling module 120 can include components such as a connection for washdown pan, three cooling fans, a panel filter wall, a recessed filter gauge, an air-cooling coil, electrical raceways, a supply air temperature sensor mounted in the fan section, and a return air path into the filter wall, as well as leak detection. Note, the pressure independent control valve for the cooling fluid is located within the piping manifold. The pressure independent control valve can be a delta P flow control valve and cooperate with the programmable logic controller.

Each air-based cooling module 120 will have an air to water cooling coil (e.g. copper tubing with mechanical fin collars), a set of three fans, a set of air filters (each 2 feet by 2 feet by 2 inches deep), electrical raceways where controls and power electrical wiring to supply electrical power for the fan, mechanical connections for the supply of facility chilled water into the air coil and return water piping. The air-based cooling module 100 casing dimensions will be able to accommodate larger fan blades (larger diameter fans are more efficient) such as 4 foot wide by 4 foot in height, and fans will be located in the draw through position (cold air is denser and improves fan efficiency). Hot return air is drawn through the filters and cooling coil (e.g., 27,300 cfm per module without suffering a significant pressure drop compared to a standard CRAH of equal flow). In addition, in order to allow for increased airflow while maintaining low pressure drop the height of the unit can be made slightly taller to be able to accommodate a slightly taller coil and slightly larger fans in an air based cooling module. According to the Fan laws (affinity laws) Fan power is proportional to cube of pressure drop, therefor it is the goal of engineers to move as much air as possible in a certain amount of real estate with the lowest amount of pressure drop. Note, in an embodiment, two upsized air-based cooling modules 120 each having their own air coil can have the same amount of power of cooling/heat rejection as one direct liquid cooling module. For example, the integrated liquid and air-cooling unit can have 500 kilowatts of air from 2 air coils and 500 kilowatts of liquid cooling in the same position in the framework.

Note, the integrated liquid and air cooling unit can also be configured to increase the heat rejection capacity of a stack of direct liquid cooling modules 140 and air-based cooling modules 120 by increasing the cross sectional flow area of the casing and equipping larger fans and coils within fan coil modules, than prior fan coils, and by adding higher capacity liquid cooling modules.

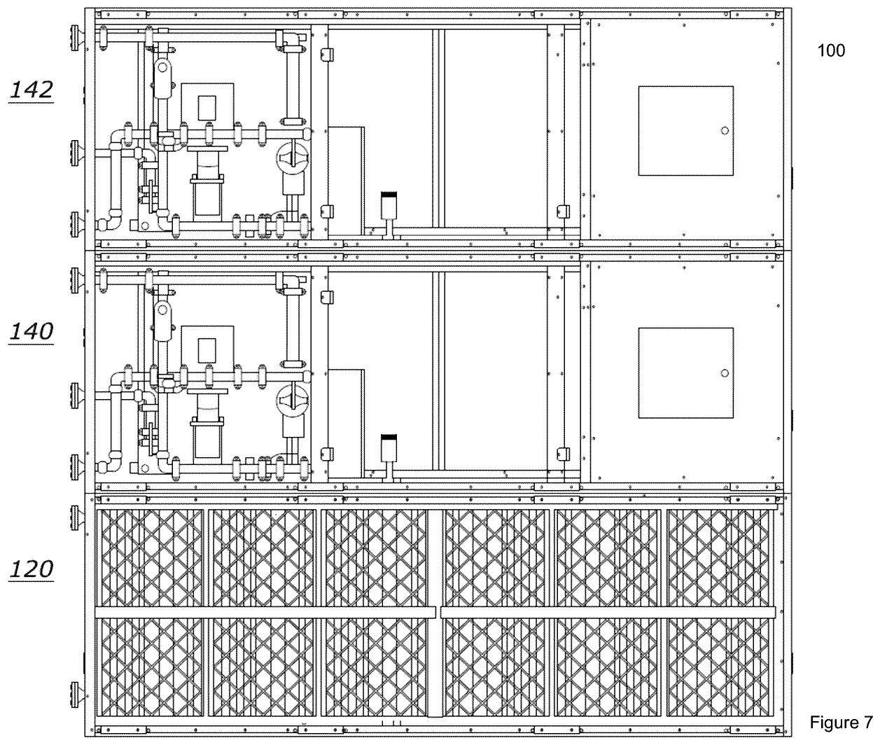

FIG. 7 illustrates a frontal view of a block diagram of an embodiment of an example integrated liquid and air cooling unit that has two direct liquid cooling modules stacked on top of a single air-based cooling module. An example stack of one air-based cooling module 120 with air filters and two direct liquid cooling modules 140, 142 is shown.

The same physical footprint (at least width and depth) of the integrated liquid and air cooling unit 100 will remain, while the height of the air-based cooling modules may vary to accommodate the increased air flow capacity and overall heat rejection capacity of the air-based cooling modules 120, thus resulting in a cumulative total increase in the integrated liquid and air cooling unit 100.

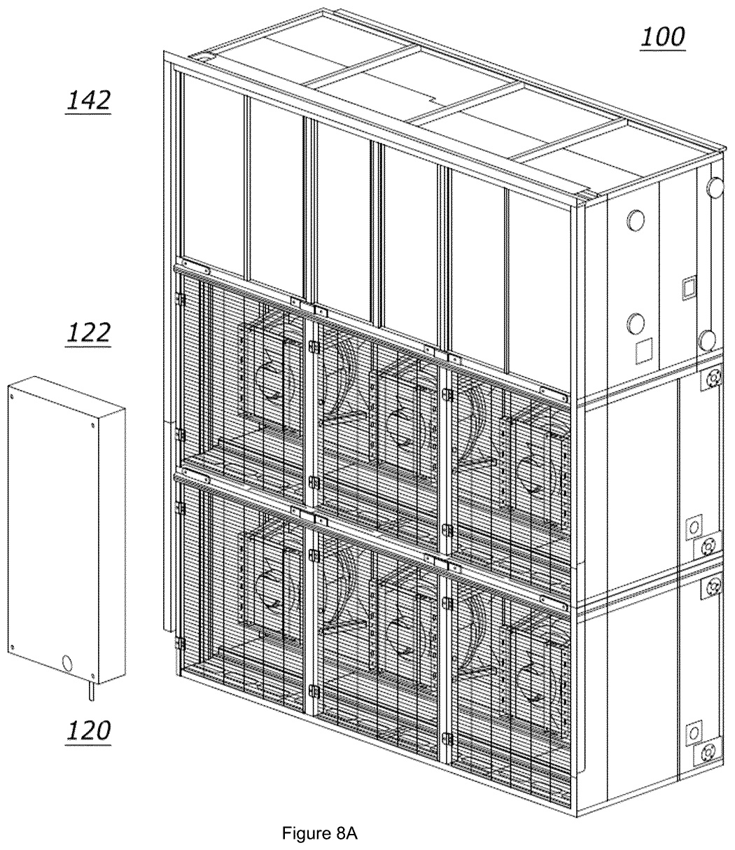

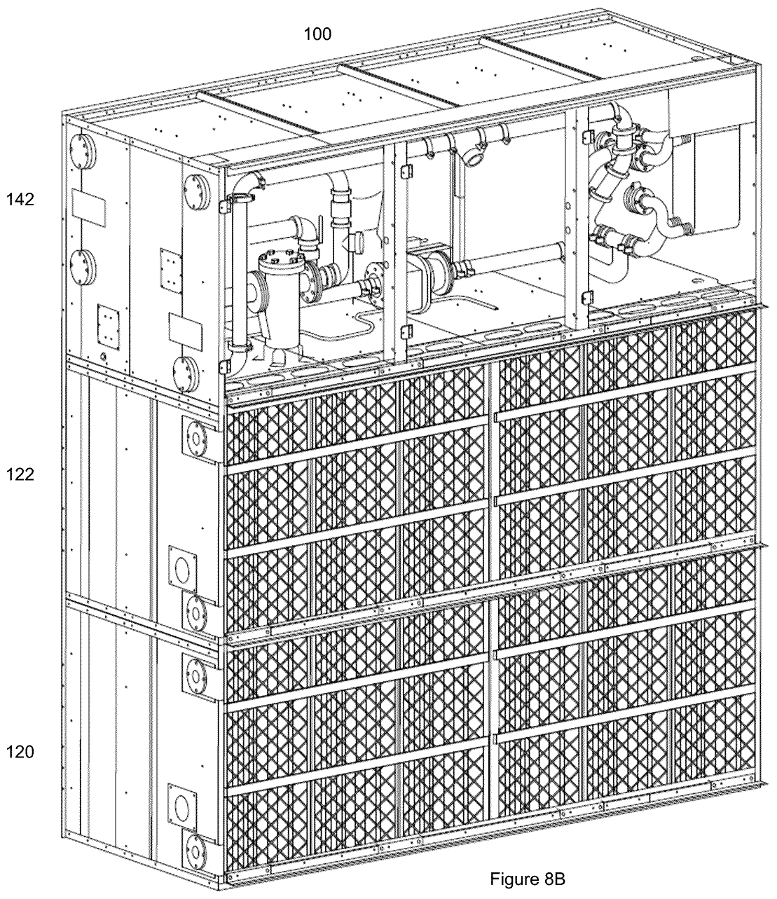

FIG. 8A illustrates a perspective view of a block diagram of an embodiment of a backside an example integrated liquid and air-cooling unit that has a single direct liquid cooling module stacked on top of two air-based cooling modules stacked. FIG. 8B illustrates a perspective view of a block diagram of an embodiment of a frontside an example integrated liquid and air-cooling unit that has a single direct liquid cooling module stacked on top of two air-based cooling modules, each with their wall of filters. An example stack of two air-based cooling modules 120, 122 with air filters and one direct liquid cooling module 140 is shown.

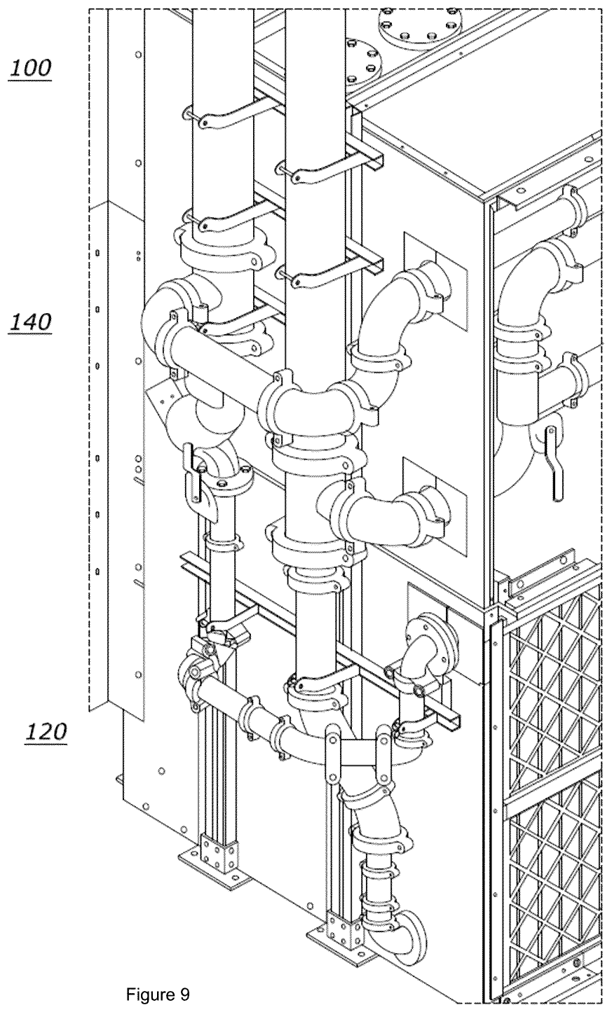

FIG. 9 illustrates a side perspective view of a block diagram of an embodiment of an example integrated liquid and air-cooling unit that has a direct liquid cooling module stacked on top of an air-based cooling module with a common piping manifold installed on a side of the integrated liquid and air cooling unit to supply a cooling fluid from the facility cooling water supply.

The integrated liquid and air cooling unit 100 also has a piping manifold connecting up to the datacenter's facility cooling water supply and water return. The piping manifold with its piping, valves, water connections, and pipe couplings attached to the framework of the integrated liquid and air cooling unit 100 has a first section for the air-based cooling and a second section for the direct liquid cooling. The facility water coming from the piping manifold does not come into direct contact with the IT computing equipment. The water from the piping manifold coming from the chilled water plant passes through the heat exchanger in the direct liquid cooling module 140 on one side of the plates in the heat exchanger to take the heat away from the fluid in the opposite side of the heat exchanger, there by transferring heat from the Technology cooling system fluid that travels through the internal portions of the IT computing equipment. The strainer on the facility water side in the direct liquid cooling module therefore does not have to be as high a grade as the TCS filters. for example, the facility side T strainer can include an 800 micron filter (˜20 mesh).

Likewise, each air-based cooling module 120 can connect up to the facility cooling water via the piping manifold to transfer the heat captured by each air-based cooling module to the facility chiller water system, and later rejected to outside ambient by way of the chiller plant.

An embodiment of the piping manifold has each air-based cooling module 120 connected individually to its own facility water header and the direct liquid cooling modules 140 connecting to a different facility water header, dependent on the thermal requirements of the two different cooling modalities (air or direct liquid). In an example, each one of these air-based cooling modules 120 can connect up to its own 2″ facility cooling fluid connection to get around 90 gallons per minute of facility cooling fluid to do its 167 kilowatts of heat rejection; and thus, a combined 3×167 kilowatts of heat removal results in 500 kilowatts of heat removal from the air cooled IT computing equipment. In another example, the combined three air-based cooling modules 120 can connect up to a common 4″ facility cooling fluid manifold with a single pressure control modulating valve to get around 300 gallons per minute (divided into 3 equal supplies of 100 gallons per minute (GPM) per module) of facility cooling fluid so that each air-based cooling module 120 may do its 167 kilowatts of heat rejection; and thus, a combined 3×167 kilowatts of heat removal results in 500 kilowatts of heat removal from the IT computing equipment. In another example, two air-based cooling modules 120 and one direct liquid cooling module 140 can share a common 6″ manifold to get around 680 gallons per minute. In this configuration, the local isolation valves allow the air-based cooling modules 120 to operate independent of whether the direct liquid cooling modules 140 is operating or is offline. The air-based cooling modules 120 would share 300 GPM (divided into 2 equal supplies of 150 GPM per module) of facility cooling fluid so that each air-based cooling module 120 may do its 250 kilowatts of heat rejection resulting in 500 kW of air cooling. Also, the one direct liquid cooling module 140 would get around 300 gallons per minute of facility cooling fluid so that the direct liquid cooling module 140 may do its 500 kilowatts of heat rejection. In another example, two air-based cooling modules 120 and one liquid cooling module can be connected to two separate 4″ facility connections such that a combined 1000 KW (500 KW Air cooling and 500 KW liquid cooling) can be achieved. Note, a benefit of the direct liquid cooling modules 140 and the air-based cooling modules 120 coupling to separate supply headers via the piping manifold allows the inlet temperature into and outlet temperatures out of the direct liquid cooling modules 140 and the air-based cooling modules 120 to be different. This allows the facility chilled water system to optimize its efficiency.

In another example, one air-based cooling module 120 and two liquid cooling modules can each be connected to separate appropriately sized facility connections such that a combined 1250 KW (250 KW Air cooling and 1000 kW Liquid Cooling) can be achieved. Given the higher specific heat capacity, higher density; and thus, lower thermal resistance of water, liquid cooled IT computing equipment; and thus, supporting direct liquid cooling modules 140 can operate at higher temperatures versus similar air-cooled IT computing equipment. This in turn allows for inlet facility water temperatures to the direct liquid cooling modules 140 to be warmer (by as much as 25 degrees C.) than inlet facility water temperatures to air cooling units. Running the facility water to the direct liquid cooling modules warmer allows for increased economization, and less total facility energy use.

The integrated liquid and air-cooling unit can also increase the total heat rejection capacity of the data center itself 1) by changing the ratio of the stack of cooperating direct liquid cooling modules 140 and air-based cooling modules 120 and/or 2) by expanding the size of air-based cooling modules 120 and equipping them with larger fans, larger chilled water cooling coils and piping connections. For example, three air-based modules each with 27,000 CFM airflow capacity may combine to remove up to 500 kilowatts. In another example, two expanded air-based modules with larger fans producing 40,000 CFM airflow capacity each with larger chilled water cooling coils and facility water connections/piping than the first example may combine to remove up to 500 kilowatts and then the direct liquid cooling module 140 within the cooperating stack will use piping and flow valves to also remove up to 500 kilowatts all in a very similar footprint space. The integrated unit maintains similar width and depth dimensions and slightly varies in height size because a bigger and taller fan is needed along with a larger surface area coil as the heat rejection capacity of that module goes up in kilowatts of heat rejection. The fan coil modules could be 27,000 CFM for 170 kilowatts of heat rejection capacity or be increased in size (for example, to 40,000 CFM for 250 kilowatts). The air-based cooling module 120 has slightly taller fans and dimensions to accommodate an additional airflow while still maintaining an exit air velocity to be below a set maximum for all air-cooled modules. Thus, the use of larger piping connections, fans, and air coil components along with another half stack of air filter just simply expands upwards to accommodate the larger equipment to get all of the air-based cooling modules 120 and the direct liquid cooling modules 140 into the same footprint size (width and depth wise) but slightly increase the height by less than a foot. Note, for the direct liquid cooling modules 140, changing the diameters of the piping, valves, and other equipment from, for example, a 2 inch to a 4-inch diameter, in order to increase the kW heat removal capability of that direct liquid cooling module 140 is easily accommodated in the same framework of a module without needing to grow the module's height.

The pressure independent control valve, in the piping manifold for the air-based cooling modules 120 and located internally in a direct liquid cooling module, controls flow through its module based on the amount of heat that the module needs to reject to stay within the temperature set point range. The amount of flow that has been put through the heat exchanger in a direct liquid cooling module 140 is relative to the temperature. Note, again, for a direct liquid cooling module 140 limits are put on the amount of openness and closedness of the pressure independent control valve so that always some amount of flow will pass through this valve to keep the flow circulating.

The pressure independent control valve can be, for example, a delta pressure valve that basically allows the controller to control the amount of flow through the facility side of the heat exchanger to take the heat away. The pressure independent control valve is selected to have a fast acting electric actuator to be able to react quickly near instantaneous heat loads as well adjustable limits so as to make sure the valve can be set to be always partially open and moving facility chilled water through the facility side of the heat exchanger and thusly heat being rejected from the Technology Cooling fluid. Obviously, when there is no heat load from the IT computing equipment being cooled from the technology cooling side, then the pressure independent control valve will modulate down and restrict the amount of facility chilled water flow, but not past a certain percentage of openness, which is adjustable. If there is no heat being generated on the Technology Cooling fluid side, then generally there is no need to flow facility cooling fluid through the facility side of the heat exchanger, but there is some nuance to that because the heat load can fluctuate and spike in milliseconds, and the pressure independent control valve actuator is not mechanically fast enough to be able to open and close rapidly enough to respond to the rate of change in the heat being pushed into that technical cooling fluid. So, one of the ways the controller is compensating for that is to limit the amount the controller will close the valve, for example, to 50%. In an embodiment, the lowest amount of modulation the controller will close the pressure independent control valve is, for example, to 25%. When the instantaneous heat load arrives, the chilled water plant along with thermal energy storage will be able to reject heat as that load ramps, because the pressure independent control valve is already partially open with the pump and heat exchanger removing heat so as to not exceed maximum temperatures allowed internally within the IT computing equipment. The GPU clusters in the IT computing equipment can cause so much instantaneous heat load so the PID controller operates the pressure independent control valve to keep the temperature of the technology cooling loop at the lowest end of the temperature set point band (hysteresis). Thus, when the heat load spikes occur, the cooling fluid for the IT computing equipment will not go out of the highest end of the allowed temperature range. In many cases, the PID controller operates the pressure independent control valve to deliver a Technology Cooling fluid setpoint that is a little bit colder than would be the most efficient operation. The customer's requirement could be, for example a 30 degrees C. for the most efficient operation, but the PID controller operates the pressure independent control valve to maintain a 24-26 degrees C. Technology Cooling System temperature set point and be a little bit less energy efficient than you would want as well as circulate facility cooling fluid even when no heat transfer is occurring.

Again, the integrated liquid and air cooling unit 100 also has a common piping manifold installed on the integrated liquid and air cooling unit 100 that is configured to connect the unit to the facility chilled water system and to supply cooling fluid to and accept a return of heated fluid from the integrated liquid and air cooling unit 100. Note, trying to pipe in connections for each separate air-based cooling module 120 and each separate direct liquid cooling module 140 all located in approximately in the same real estate area of the datacenter each module with its own separate facility chilled water supply and water return piping would be very challenging. Also, with the integrated liquid and air cooling unit 100, the datacenter does not need separate liquid coiling units and separate air handlers occupying separate real estate spaces in the datacenter.

The piping manifold has a mix of straight sections of pipe with bended couplings, isolation valves, and saddles to enable easily isolating a particular air-based cooling module 120 or direct liquid cooling module 140 for subsequent maintenance or replacement. Again, each air-based and direct liquid based cooling module is designed to have its internal piping slide in and mate up to the piping connections provided by the piping manifold. Note, given the piping length requirements entering and leaving a typical pressure independent control valve, and the resulting reduction in accuracy for other types of pressure independent control valve, the pressure independent control valve can be a Delta P pressure valve. The Delta P pressure independent control valve is able to deliver more accurate and consistent flow without the need for lengthy straight entering and leaving piping sections. The Delta P pressure independent control valve can be located right after another fitting or a bend.

Next, in the direct liquid cooling module 140 the water inlet and outlets can also be located on the top of, or out in the front of the unit, rather than the side of the integrated liquid and air cooling unit 100 depending on the orientation of the integrated liquid and air cooling unit 100 and its best alignment with the Technology Cooling System Some datacenters can route the Technology Cooling System piping on the walls around rack height or along the ceiling, or under a raised floor. The water inlet and outlets can be routed as built to order or through punch-out holes in the framework of a discrete air-based cooling module 120 or direct liquid cooling module 140 as well as then through the framework of the integrated liquid and air-cooling unit. Where two direct liquid cooling modules 100 are stacked in the same position, their TCS water inlet and outlet connections can be connected in series so that only a single injection point to the TCS is needed.

Lastly, an electrical panel can be built into the end of the air-based cooling module 120 with enough circuit breakers to power all the fan units inside a full complement of air cooling modules 120.

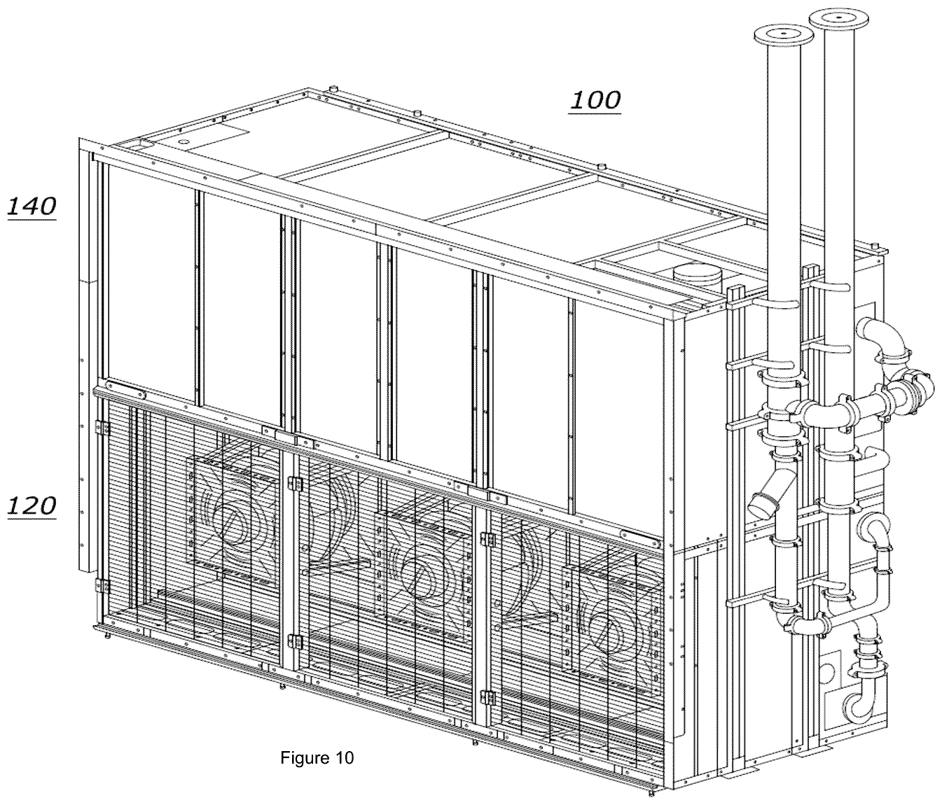

FIG. 10 illustrates a perspective view of a block diagram of an embodiment of a backside of an example integrated liquid and air-cooling unit that has a direct liquid cooling module stacked on top of an air-based cooling module with a common piping manifold connecting to a side of the integrated liquid and air cooling unit 100 to supply a cooling fluid from the facility cooling water supply. The integrated liquid and air cooling unit 100 for a datacenter gives the ability to use distributed redundant piping topologies. The integrated liquid and air cooling unit 100 provides multiple units feeding an entire datacenter of IT racks system versus a 2 N arrangement across a smaller load center such as a single row of racks. Another benefit is the higher leverage redundancy profile can be used, such as: N+4 and/or N+1 across multiple rows-compared to typical 2N scheme. This distributed redundancy allows us to deliver concurrent maintainability, fault tolerance, and overall availability requirements with significantly less equipment (for example: an 8 MW data hall made up of 500 KW IT Rows, would traditionally have 32 direct liquid cooling modules, while our design would reduce that to 20). That is a big advantage, not only from the direct liquid cooling modules equipment cost perspective, but also from a piping, telemetry, maintenance, and water treatment perspective.

The integrated liquid and air cooling unit 100 also provides maintenance access through a mechanical gallery versus access needed in a customer white space of server/IT racks in the datacenter. The IT equipment such as servers, databases, routers, etc. are aligned in the racks in the white space, and the integrated liquid and air cooling unit 100 is located in the green mechanical galleries. In addition, most of today's direct liquid cooling designs utilize CDU's that are placed in line with the row of IT equipment in the “whitespace”, while the integrated liquid and air cooling unit 100 is placed in the mechanical gallery; and therefore, unlike the competition, our maintenance doesn't have to be carried out in the whitespace of where the IT equipment is located, but rather the physically different space of the mechanical gallery. Most customers prefer this because the maintenance personnel do not need authorization from every customer to access the space where their IT computing equipment is located. Instead, the mechanical gallery is a physically separate area where maintenance personal do not need authorization from any customer but merely the datacenter operator to access the space where the integrated liquid and air cooling unit 100 is placed. Each separate customer may have their own set of IT computing equipment inside a secure cage being cooled by the integrated liquid and air cooling unit 100 cooling all of the IT computing equipment in that data floor.

The integrated liquid and air cooling unit 100 takes the onus off the customer to provide liquid cooling equipment for a future unknown capacity amount and in an unknown configuration. The integrated liquid and air cooling unit 100 provides the liquid at the right conditions, at the right cleanliness with the right availability, and offers various redundancy arrangements with the flexibility to deploy as much or little liquid cooled capacity as is needed when it arrives.

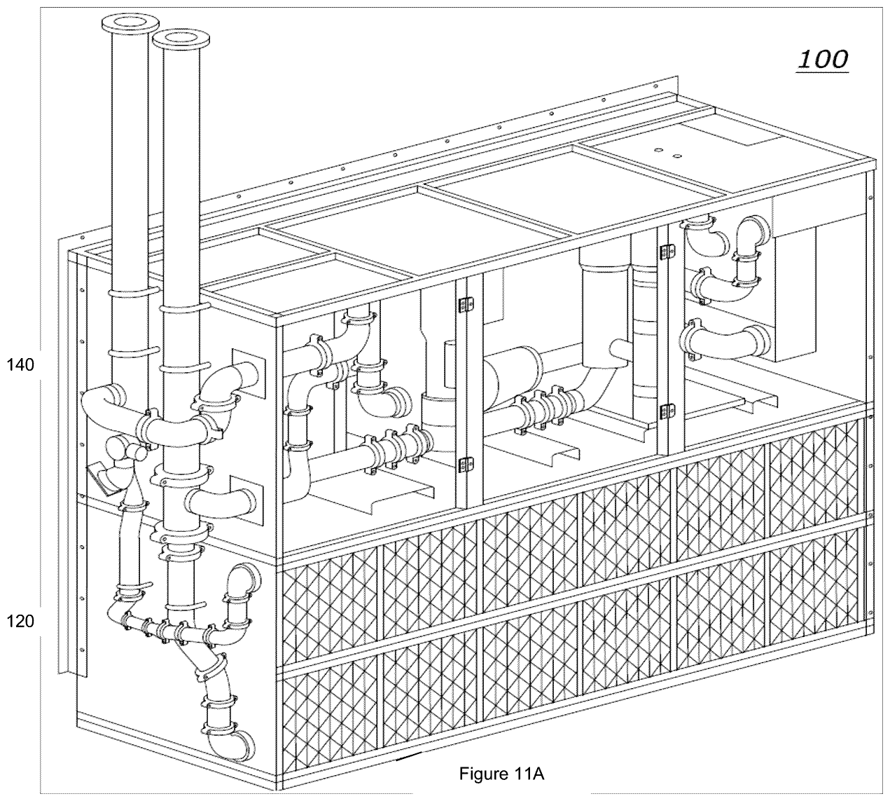

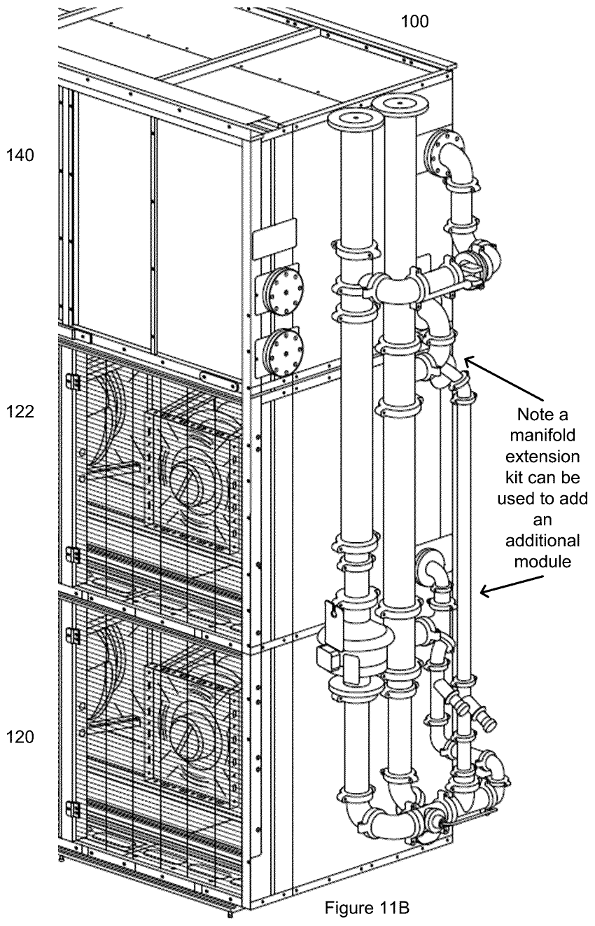

FIG. 11A illustrates a perspective view of a block diagram of an embodiment of a front side an example integrated liquid and air cooling unit that has a frame and structure of the integrated liquid and air cooling unit 100 constructed with a common piping manifold integrated onto the integrated liquid and air cooling unit 100 such that a first ratio of air-based cooling modules compared to direct liquid cooling modules is installed on the integrated liquid and air cooling unit at day one of an operation of the datacenter, and then be configurable to be a second ratio of air-based cooling modules compared to direct liquid cooling modules installed on the integrated liquid and air cooling unit at a later day of an operation than day one of the datacenter in order to supply a different heat removal need of the IT computing equipment in a future operation of the datacenter.

FIG. 11B illustrates a perspective view of a block diagram of an embodiment of a front side an example integrated liquid and air cooling unit 100 that has a frame and structure of the integrated liquid and air cooling unit constructed with a common extended piping manifold (extension kit noted) integrated onto the integrated liquid and air cooling unit such that a second ratio of air-based cooling modules compared to direct liquid cooling modules is installed on the integrated liquid and air cooling unit at a future day of an operation of the datacenter.

FIG. 13A illustrates a top-down view of a diagram of an embodiment of an example a direct liquid cooling module 140 with similar components arranged slightly differently than FIG. 12A. The direct liquid cooling module 140 can include components such as a heat exchanger, an electrical vestibule, a dual capacity basket strainer and bag filter, a T-strainer, a pump, and a pressure independent control valve and flow and pressure sensors.

FIG. 13B illustrates a top-down view of a diagram of an embodiment of an example an air-based cooling module. The air-based cooling module 120 can include components such as a connection for washdown pan, three cooling fans, a panel filter wall, a recessed filter gauge, an air-cooling coil, electrical raceways, a supply air temperature sensor mounted in the fan section, and a return air path into the filter wall. Note, the pressure independent control valve for the cooling fluid for the air-based cooling module is located outside the casing in the modular piping manifold.

Since the integrated liquid and air cooling unit is modular, there are potential financial and environmental sustainability benefits to be gained through the reuse of air-based cooling modules and direct liquid cooling modules in future data halls. These savings can impact the rent rate and provide the lessor/owner with a competitive advantage over existing technology and competitors.

The methods and systems shown in the Figures and discussed in the text herein can be coded to be performed, at least in part, by one or more processing components with any portions of software stored in an executable format on a computer readable medium. Thus, any portions of the method, apparatus and system implemented as software can be stored in one or more non-transitory memory storage devices in an executable format to be executed by one or more processors. The computer readable medium may be non-transitory and does not include radio or other carrier waves. The computer readable medium could be, for example, a physical computer readable medium such as semiconductor memory or solid-state memory, magnetic tape, a removable computer diskette, a random-access memory (RAM), a read-only memory (ROM), a rigid magnetic disc, and an optical disk, such as a CD-ROM, CD-R/W or DVD. The various methods described above may also be implemented by a computer program product. The computer program product may include computer code arranged to instruct a computer to perform the functions of one or more of the various methods described above. The computer program and/or the code for performing such methods may be provided to an apparatus, such as a computer, on a computer readable medium or computer program product. For the computer program product, a transitory computer readable medium may include radio or other carrier waves.

A computing system can be, wholly or partially, part of one or more of the server or client computing devices in accordance with some embodiments. Components of the computing system can include, but are not limited to, a processing unit having one or more processing cores, a system memory, and a system bus that couples various system components including the system memory to the processing unit.

### Computing Devices

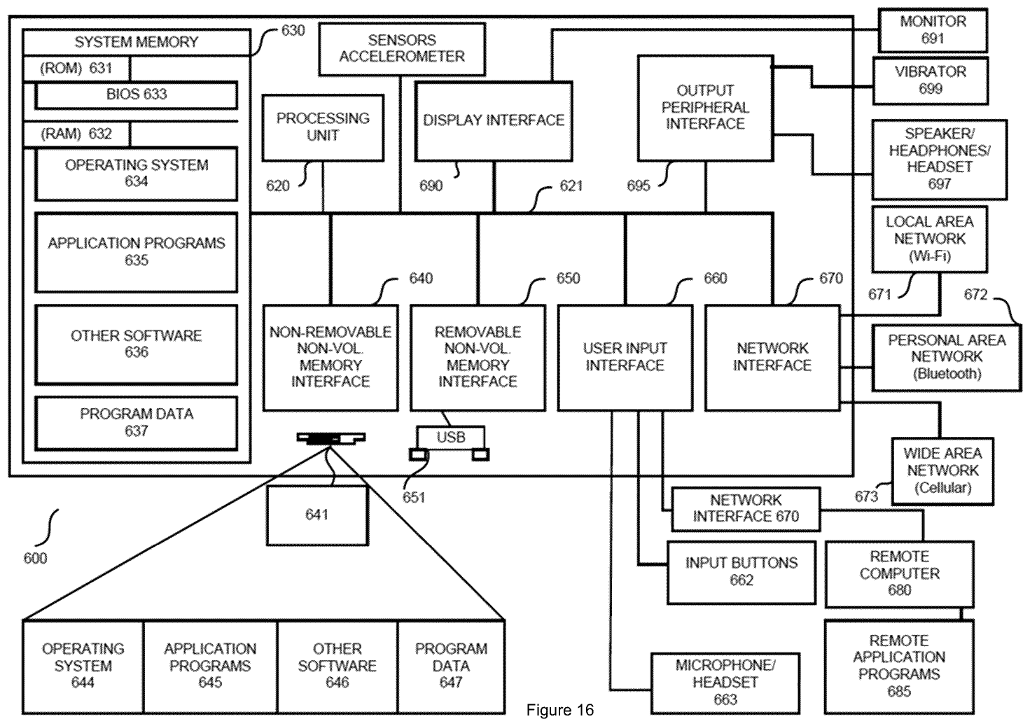

FIG. 16 illustrates a block diagram of an embodiment of an example computing device that can be a part of the integrated liquid and air cooling unit and data center equipment discussed herein.

The computing device may include one or more processors or processing units 620 to execute instructions, one or more memories 630-632 to store information, one or more data input components 660-663 to receive data input from a user of the computing device 600, one or more modules that include the management module, a network interface communication circuit 670 to establish a communication link to communicate with other computing devices external to the computing device, one or more sensors where an output from the sensors is used for sensing a specific triggering condition and then correspondingly generating one or more preprogrammed actions, a display screen 691 to display at least some of the information stored in the one or more memories 630-632 and other components. Note, portions of this design implemented in software 644, 645, 646 are stored in the one or more memories 630-632 and are executed by the one or more processors 620. The processing unit 620 may have one or more processing cores, which couples to a system bus 621 that couples various system components including the system memory 630. The system bus 621 may be any of several types of bus structures selected from a memory bus, an interconnect fabric, a peripheral bus, and a local bus using any of a variety of bus architectures.

Computing device 600 typically includes a variety of computing machine-readable media. Machine-readable media can be any available media that can be accessed by computing device 600 and includes both volatile and nonvolatile media, and removable and non-removable media. By way of example, and not limitation, computing machine-readable media use includes storage of information, such as computer-readable instructions, data structures, other executable software, or other data. Computer-storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other tangible medium which can be used to store the desired information, and which can be accessed by the computing device 600. Transitory media such as wireless channels are not included in the machine-readable media. Machine-readable media typically embody computer readable instructions, data structures, and other executable software. In an example, a volatile memory drive 641 is illustrated for storing portions of the operating system 644, application programs 645, other executable software 646, and program data 647.

A user may enter commands and information into the computing device 600 through input devices such as a keyboard, touchscreen, or software or hardware input buttons 662, a microphone 663, a pointing device and/or scrolling input component, such as a mouse, trackball, or touch pad 661. The microphone 663 can cooperate with speech recognition software. These and other input devices are often connected to the processing unit 620 through a user input interface 660 that is coupled to the system bus 621, but can be connected by other interface and bus structures, such as a lighting port, game port, or a universal serial bus (USB). A display monitor 691 or other type of display screen device is also connected to the system bus 621 via an interface, such as a display interface 690. In addition to the monitor 691, computing devices may also include other peripheral output devices such as speakers 697, a vibration device 699, and other output devices, which may be connected through an output peripheral interface 695.

The computing device 600 can operate in a networked environment using logical connections to one or more remote computers/client devices, such as a remote computing system 680. The remote computing system 680 can a personal computer, a mobile computing device, a server, a router, a network PC, a peer device, or other common network node, and typically includes many or all of the elements described above relative to the computing device 600. The logical connections can include a personal area network (PAN) 672 (e.g., Bluetooth®), a local area network (LAN) 671 (e.g., Wi-Fi), and a wide area network (WAN) 673 (e.g., cellular network). Such networking environments are commonplace in offices, enterprise-wide computer networks, intranets, and the Internet. A browser application and/or one or more local apps may be resident on the computing device and stored in the memory.

When used in a LAN networking environment, the computing device 600 is connected to the LAN 671 through a network interface 670, which can be, for example, a Bluetooth® or Wi-Fi adapter. When used in a WAN networking environment (e.g., Internet), the computing device 600 typically includes some means for establishing communications over the WAN 673. With respect to mobile telecommunication technologies, for example, a radio interface, which can be internal or external, can be connected to the system bus 621 via the network interface 670, or other appropriate mechanism. In a networked environment, other software depicted relative to the computing device 600, or portions thereof, may be stored in the remote memory storage device. By way of example, and not limitation, remote application programs 685 as reside on remote computing device 680. It will be appreciated that the network connections shown are examples and other means of establishing a communications link between the computing devices that may be used. It should be noted that the present design can be carried out on a single computing device or on a distributed system in which different portions of the present design are carried out on different parts of the distributed computing system.

Note, an application described herein includes but is not limited to software applications, mobile applications, and programs routines, objects, widgets, plug-ins that are part of an operating system application. Some portions of this description are presented in terms of algorithms and symbolic representations of operations on data bits within a computer memory. These algorithmic descriptions and representations are the means used by those skilled in the data processing arts to convey the substance of their work most effectively to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like. These algorithms can be written in a number of different software programming languages such as Python, C, C++, Java, HTTP, or other similar languages. Also, an algorithm can be implemented with lines of code in software, configured logic gates in hardware, or a combination of both. In an embodiment, the logic consists of electronic circuits that follow the rules of Boolean Logic, software that contain patterns of instructions, or any combination of both. A non-mechanical module may be implemented in hardware electronic components, software components, and a combination of both. A software engine is a core component of a complex system consisting of hardware and software that is capable of performing its function discretely from other portions of the entire complex system but designed to interact with the other portions of the entire complex system.

Unless specifically stated otherwise as apparent from the above discussions, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system's registers and memories into other data similarly represented as physical quantities within the computer system memories or registers, or other such information storage, transmission or display devices.

The terms “or” and “and/or” as used herein are to be interpreted as inclusive or meaning any one or any combination. Therefore, “A, B or C” or “A, B and/or C” mean “any of the following: A; B; C; A and B; A and C; B and C; A, B and C.” An exception to this definition will occur only when a combination of elements, functions, steps, or acts are in some way inherently mutually exclusive.

While some specific embodiments of the design have been shown, the design is not to be limited to these embodiments. The design is to be understood as not limited by the specific embodiments described herein, but only by the scope of the appended claims. Moreover, specific components and various embodiments have been shown and described. It should be understood that the invention covers any combination, sub-combination, or re-combination, including duplicating components, subtracting components, combination components, integrating components, separating components, and/or dividing components.

The terms “approximately” and “about” are used interchangeably to indicate that the disclosed and suggested values do not require exact precision. The relative inclusions of values around each value depends on the error in building, manufacturing, and installing the components, as is generally practiced by a person of skill in the art. Even without the specific identification of approximation (i.e. the term “about” or “approximate”), all of the dimensions disclosed are examples only and include equivalent or approximate values to the stated value to achieve similar, equal, or better benefits or effects to those of the disclosed dimensions.

1. An apparatus, comprising:
an integrated liquid and air cooling unit that has a framework constructed to contain and support a weight of one or more air-based cooling modules and one or more direct liquid cooling modules, in a same real estate space, to supply air-based cooling and direct liquid cooling to Information Technology (IT) computing equipment housed in a datacenter.

2. The apparatus of claim 1, where the integrated liquid and air cooling unit also has a common piping manifold installed on the integrated liquid and air cooling unit that is configured to connect facility cooling water to supply cooling fluid and accept a return of heated fluid from an air coil in a first air-based cooling module and a heat exchanger in a first direct liquid cooling module in order to reject heat out of the datacenter and the IT computing equipment housed within the datacenter.

3. The apparatus of claim 1, where a frame and structure of a cabinetry of the integrated liquid and air cooling unit are constructed to accommodate a weight of 1) a first air-based cooling module or a first direct liquid cooling module stacked on top of 2) a second air-based cooling module or a second direct liquid cooling module, as well as, to allow either the first air-based cooling module or the first direct liquid cooling module to slide into a same designed space of the framework and mechanically connect up to a same facility water connections, where each air-based cooling module and each direct liquid cooling module, has substantially a same width and depth dimensions, and the same facility water connections such that a first direct liquid cooling module can be swapped with a first air-based cooling module in the same designed space of the framework.

4. The apparatus of claim 1, where a first direct liquid cooling module and/or a first air-based cooling module in the integrated liquid and air cooling unit is constructed to be integrated and bolted together in a same stack with a second direct liquid cooling module and/or a second air-based cooling module in the integrated liquid and air cooling unit, as well as be unbolted to come apart in order to change out the first air-based cooling module for a third direct liquid cooling module to switch a cooling modality of the datacenter over a lifetime of the datacenter.

5. The apparatus of claim 1, where a frame and structure of the integrated liquid and air cooling unit are constructed with a common piping manifold integrated onto the integrated liquid and air cooling unit such that a first ratio of air-based cooling modules compared to direct liquid cooling modules is installed on the integrated liquid and air cooling unit at day one of an operation of the datacenter, and then be configurable to be a second ratio of air-based cooling modules compared to direct liquid cooling modules installed on the integrated liquid and air cooling unit at a later day of an operation than day one of the datacenter in order to supply a different heat removal need of the IT computing equipment in a future operation of the datacenter.

6. The apparatus of claim 1, where the integrated liquid and air cooling unit further has two or more controllers installed and associated with the air-based cooling modules and the direct liquid cooling modules that are configured to allow bifurcated temperature zones in a sense that 1) a first controller is programmed to control and operate a first air-based cooling module to supply cooling to maintain a first temperature set point for IT computing equipment being cooled by the first air-based cooling module and 2) a second controller is programmed to control and operate a first direct liquid cooling module to supply cooling to maintain a second temperature set point for IT computing equipment being cooled by the first direct liquid cooling module.

7. The apparatus of claim 1, where a first air-based cooling module has its own casing, a set of two or more fans, an air coil, an air filter, and a pressure control modulating valve located on an outside frame of the first air-based cooling module as part of a piping manifold.

8. The apparatus of claim 1, where a first direct liquid cooling module has its own casing and internal components including a heat exchanger, a T-strainer, a high capacity basket strainer, a pump, a pressure independent control valve, and its own controller.

9. The apparatus of claim 1, where a first direct liquid cooling module has its own casing and internal components including a heat exchanger, a dual capacity basket strainer and bag filter, and a pump, where the dual capacity basket strainer and bag filter is used on an internal cooling side for the IT computing equipment being cooled by the first direct liquid cooling module.

10. The apparatus of claim 1, where a first direct liquid cooling module has a heat exchanger, a pump, and a pressure independent control valve, where the pressure independent control valve is configured to not be able to close completely; and thus, always allow facility cooling fluid flow to move through the pressure independent control valve and facility side of the heat exchanger; thereby, continuously transferring heat from a technology cooling system side and ultimately from IT computing equipment being cooled by the first direct liquid cooling module when the IT computing equipment is in operation.

11. A method to cool a datacenter, comprising:
providing an integrated liquid and air cooling unit that has a framework constructed to contain and support a weight of one or more air-based cooling modules and one or more direct liquid cooling modules, in a same real estate space, to supply air-based cooling and direct liquid cooling for Information Technology (IT) computing equipment housed in the datacenter.

12. The method of claim 11, further comprising:
providing the integrated liquid and air cooling unit with a common piping manifold installed on the integrated liquid and air cooling unit in order to connect facility cooling water to supply cooling fluid and accept a return of heated fluid from an air coil in a first air-based cooling module and a heat exchanger in a first direct liquid cooling module; and thus, transfer heat out of the datacenter and the IT computing equipment housed within the datacenter.

13. The method of claim 11, further comprising:
providing a frame and structure of a cabinetry of the integrated liquid and air cooling unit to accommodate a weight of 1) a first air-based cooling module or a first direct liquid cooling module stacked on top of 2) a second air-based cooling module or a second direct liquid cooling module, as well as, to allow either the first air-based cooling module or the first direct liquid cooling module to slide into a same designed space of the framework and mechanically connect up to a same facility water connections, where each air-based cooling module and each direct liquid cooling module, has substantially a same width and depth dimensions, and the same facility water connections such that a first direct liquid cooling module can be swapped with a first air-based cooling module in the same designed space of the framework.

14. The method of claim 11, further comprising:
providing at least one of a first direct liquid cooling module and a first air-based cooling module in the integrated liquid and air cooling unit, where the first direct liquid cooling module and/or the first air-based cooling module is constructed to be integrated and bolted together in a same stack with a second direct liquid cooling module and/or a second air-based cooling module in the integrated liquid and air cooling unit, as well as be unbolted to come apart in order to change out the first air-based cooling module for a third direct liquid cooling module to switch a cooling modality of the datacenter over a lifetime of the datacenter.

15. The method of claim 11, further comprising:
providing a frame and structure of the integrated liquid and air cooling unit with a common piping manifold integrated onto the integrated liquid and air cooling unit such that a first ratio of air-based cooling modules compared to direct liquid cooling modules is installed on the integrated liquid and air cooling unit at day one of an operation of the datacenter, and then be configurable to be a second ratio of air-based cooling modules compared to direct liquid cooling modules installed on the integrated liquid and air cooling unit at a later day of an operation than day one of the datacenter in order to supply a different heat removal need of the IT computing equipment in a future operation of the datacenter.

16. The method of claim 11, further comprising:
providing the integrated liquid and air cooling unit further with two or more controllers installed and associated with the air-based cooling modules and the direct liquid cooling modules to allow bifurcated temperature zones in a sense that 1) a first controller is programmed to control and operate a first air-based cooling module to supply cooling to maintain a first temperature set point for IT computing equipment being cooled by the first air-based cooling module and 2) a second controller is programmed to control and operate a first direct liquid cooling module to supply cooling to maintain a second temperature set point for IT computing equipment being cooled by the first direct liquid cooling module.

17. The method of claim 11, further comprising:
providing a first air-based cooling module with its own casing, a set of two or more fans, an air coil, an air filter, and a pressure control modulating valve located on an outside frame of the first air-based cooling module as part of a piping manifold.

18. The method of claim 11, further comprising:
providing a first direct liquid cooling module with its own casing and internal components including a heat exchanger, a T-strainer, a pump, a pressure independent control valve, and its own controller.

19. The method of claim 11, further comprising:
providing a first direct liquid cooling module with its own casing and internal components including a heat exchanger, a T-strainer, a dual capacity basket strainer and bag filter and a pump, where the dual capacity basket strainer and bag filter is used on an internal cooling side for the IT computing equipment being cooled by the first direct liquid cooling module so as to insure low risk of particulate contamination while also maintaining steady flow and low pump power.

20. The method of claim 11, further comprising:
providing a first direct liquid cooling module with a heat exchanger, a pump, and a pressure independent control valve, where the pressure independent control valve is configured to not be able to close completely; and thus, always allow cooling flow to move through the pressure independent control valve and facility side of the heat exchanger; thereby, continuously transferring heat from a technology cooling system side and ultimately from the IT computing equipment being cooled by the first direct liquid cooling module when the IT computing equipment is in operation.
